(19) United States
(12) Patent Application Publication
(10) Pub. No.: US 2026/0090090 A1
(43) Pub. Date: Mar. 26, 2026

(54) STACKED SEMICONDUCTOR DEVICES AND METHODS OF MANUFACTURING THE SAME

(71) Applicant: Taiwan Semiconductor Manufacturing Company, Ltd., Hsinchu (TW)

(72) Inventors: Chun-Yen Lin, Tainan City (TW); Wei-Cheng Lin, Hsinchu County (TW); Jiann-Tyng Tzeng, Hsinchu County (TW)

(73) Assignee: Taiwan Semiconductor Manufacturing Company, Ltd., Hsinchu (TW)

(21) Appl. No.: 19/178,211

(22) Filed: Apr. 14, 2025

Related U.S. Application Data
(60) Provisional application No. 63/699,331, filed on Sep. 26, 2024.

(51) Int. Cl. H10D 84/85; H10D 30/00; H10D 30/01; H10D 30/43; H10D 62/10; H10D 84/01

(52) U.S. Cl. CPC H10D 84/851; H10D 30/014; H10D 30/0191; H10D 30/43; H10D 30/502; H10D 62/102; H10D 62/121; H10D 84/0188; H10D 84/856

(57) ABSTRACT

A semiconductor device includes an active gate structure disposed over a substrate; first source/drain features disposed at two opposite sides of the active gate structure; a dielectric gate structure disposed over the substrate, the dielectric gate structure and the active gate structure stacked one over another along a vertical direction perpendicular to the substrate; and second source/drain features disposed at two opposite sides of the dielectric gate structure, where the first source/drain features and the second source/drain features are of different conductivity types.

### CROSS-REFERENCE TO RELATED APPLICATIONS

This application claims priority from U.S. Provisional Patent Application No. 63/699,331, filed Sep. 26, 2024, the entire disclosure of which is incorporated herein by reference for all purposes.

### BACKGROUND

Semiconductor devices are used in a variety of electronic applications, such as personal computers, cell phones, digital cameras, and other electronic equipment. Semiconductor devices are fabricated by sequentially depositing insulating or dielectric layers, conductive layers, and semiconductor layers of material over a substrate, and patterning the various material layers using lithography to form circuit components and elements thereon.

As the semiconductor industry has progressed into nanometer technology process nodes, a number of three-dimensional designs have emerged recently in pursuit of higher device density, improved performance, lowered costs. These devices may include, for example, metal-oxide-semiconductor field effect transistors (MOSFET), field effect transistors (FET), fin field effect transistor (FinFET), gate-all-around (GAA) devices (nanowires/nanosheets), GAA devices configured as complementary field effect transistor (CFET) devices, and multi-bridge channel field effect transistor (MBCFET) devices (nanosheets). While such devices have been generally adequate for improving various device performance, they have not been entirely satisfactory in all aspects.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1 and 4 each illustrate a three-dimensional perspective view of a semiconductor device having a vertically stacked structure, in portion or in entirety, in accordance with some embodiments.

FIGS. 2 and 5 each illustrate a cross-sectional view taken along a line AA′ of the semiconductor device shown in FIGS. 1 and 4, respectively, in portion or in entirety, in accordance with some embodiments.

FIGS. 3 and 6 each illustrate a cross-sectional view taken along a line BB′ of the semiconductor device shown in FIGS. 1 and 4, respectively, in portion or in entirety, in accordance with some embodiments.

FIG. 7 illustrates a circuit diagram of a semiconductor device having a vertically stacked structure, in portion or in entirety, in accordance with some embodiments.

FIG. 8 illustrates a frontside view of an example layout design corresponding to the semiconductor device illustrated in FIG. 7, in portion or in entirety, in accordance with some embodiments.

FIG. 9 illustrates a backside view of an example layout design corresponding to the semiconductor device illustrated in FIG. 7, in portion or in entirety, in accordance with some embodiments.

FIG. 10 illustrates a flowchart of a method of manufacturing a semiconductor device, in accordance with some embodiments.

FIG. 11 illustrates a block diagram of a system of generating an IC layout design, in accordance with some embodiments.

FIG. 12 illustrates a block diagram of an IC manufacturing system, and an IC manufacturing flow associated therewith, in accordance with some embodiments.

FIG. 13 illustrates a flowchart of a method of manufacturing a semiconductor device having a vertically stacked structure, in portion or in entirety, in accordance with some embodiments.

FIG. 14 illustrates a flowchart of a method for implementing a portion of the method as illustrated in the flowchart of FIG. 13, in accordance with some embodiments.

FIGS. 15 and 19 each illustrate a three-dimensional perspective view of a portion of a semiconductor device having a vertically stacked structure at an intermediate stage of the method illustrated in the flowchart of FIG. 14, in accordance with some embodiments.

FIGS. 16, 17, 18, 20, 22, 24, 26, 27, and 28 each illustrate a cross-sectional view taken along line CC′ of the semiconductor device illustrated in FIG. 15, in portion or in entirety, at an intermediate stage of the method illustrated in the flowchart of FIG. 14, in accordance with some embodiments.

FIGS. 21, 23, and 25 each illustrate a cross-sectional view taken along line DD′ of the semiconductor device illustrated in FIG. 15, in portion or in entirety, at an intermediate stage of the method illustrated in the flowchart of FIG. 14, in accordance with some embodiments.

FIG. 29 illustrates a flowchart of a method of manufacturing a semiconductor device having a vertically stacked structure, in portion or in entirety, in accordance with some embodiments.

### DETAILED DESCRIPTION

The following disclosure provides many different embodiments, or examples, for implementing different features of the provided subject matter. Specific examples of components, values, operations, materials, arrangements, or the like, are described below to simplify the present disclosure. These are, of course, merely examples and are not intended to be limiting. Other components, values, operations, materials, arrangements, or the like, are contemplated. For example, the formation of a first feature over or on a second feature in the description that follows may include embodiments in which the first are formed in direct contact the second features and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The structures and methods detailed below relate to structures, designs, and manufacturing methods for CFET IC devices. In some embodiments, a stack of semiconductor devices comprises a top or upper semiconductor device that is physically stacked over a bottom or lower semiconductor device along a vertical direction. For simplicity, a stack of semiconductor devices is sometimes referred to as a device stack. Depending on the device design, the included device stacks (e.g., a CFET structure) comprise stacked semiconductor devices of the same conductivity type and/or device stacks in which the stacked semiconductor devices are of different conductivity types. For instances, an n-type metal-oxide-semiconductor (NMOS) transistor may be vertically stacked over a p-type metal-oxide-semiconductor (PMOS) transistor. In some embodiments, by configuring semiconductor devices in device stacks, the required chip area is reduced by up to 50%.

While CFET structures have generally enhanced target performance of IC devices as described above with respect to area-saving benefits, they have not been entirely satisfactory in all aspects. In some instances, it may be desirable to independently adjust one of the two stacked devices to achieve a skewed effect in the performance of the complementary device (e.g., a pair of NMOS and PMOS devices). For example, it may be desirable to deactivate the NMOS device without substantially affecting the PMOS device to achieve matched current levels between the two stacked devices without substantially altering channel widths of the devices or inadvertently increasing device capacitance.

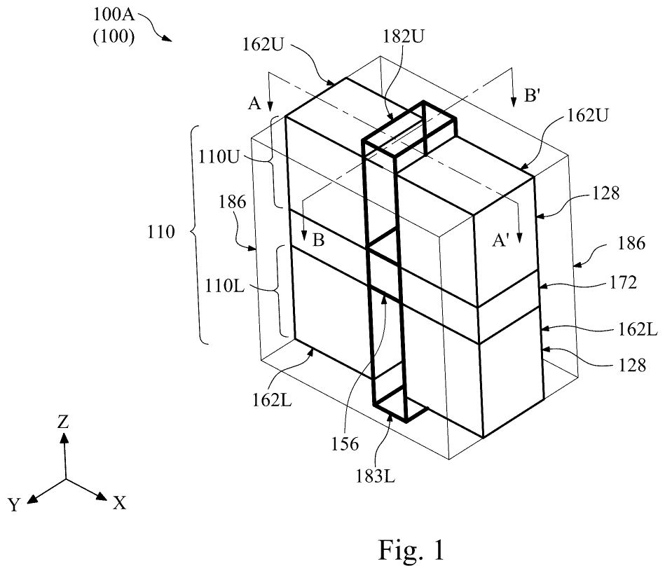

FIG. 1 illustrates a schematic perspective view of an embodiment of a semiconductor device 100A (hereafter referred to as device 100A), in portion or in entirety, according to some embodiments of the present disclosure. The device 100A includes a multilayer structure 110 (e.g., multilayer structure 910 described below) having a lower (or first) device 110L (e.g., lower device 910L described below) and an upper (or second) device 110U (e.g., upper device 910U described below) stacked over the lower device 110L. A fin 128 (e.g., fin 928 described below; alternatively referred to as an active region 128) of each of the lower device 110L and the upper device 110U extends lengthwise along a first direction (e.g., the X-direction). While only one fin 128 is depicted herein, the device 100A may include any suitable number of fins 128 disposed over the substrate, where adjacent fins 128 (not depicted herein) are spaced apart along a second direction (e.g., the Y-direction) perpendicular to the first direction in a top view of the device 100A.

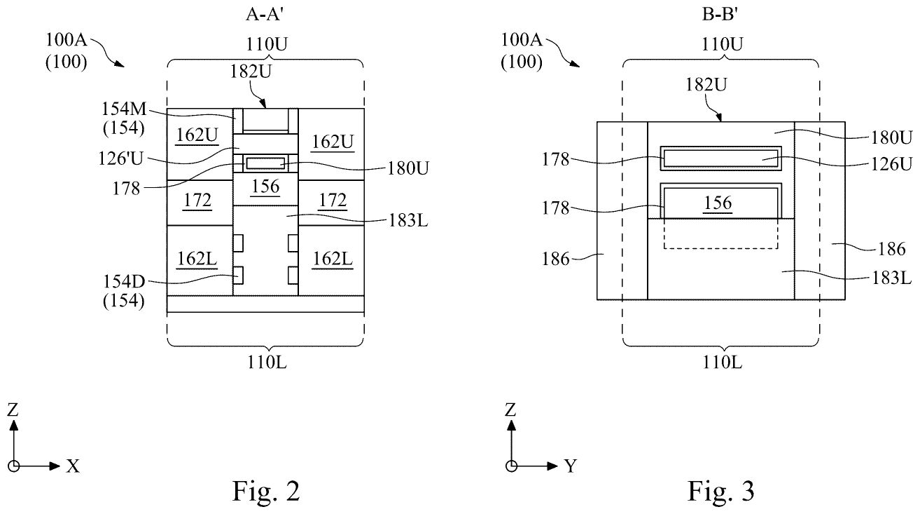

The lower device 110L is disposed over a frontside (FS) of a substrate (e.g., substrate 920 described below; not depicted herein). The upper device 110U is physically stacked over the lower device 110L on the frontside of the substrate along a third direction (e.g., the Z-direction) that is perpendicular to each of the first direction and the second direction in a cross-sectional view (as depicted in each of FIGS. 2 and 3, for example) of the device 100A. In this regard, the lower device 110L is disposed between the substrate and the upper device 110U along the third direction. Stated differently, the lower device 110L is disposed in closer proximity to the frontside of the substrate than the upper device 110U along the third direction. In some embodiments, the first direction, second direction, third direction are mutually transverse to each other. In some embodiments, the first direction, second direction, third direction are mutually perpendicular to each other as described herein.

The present disclosure provides a CFET structure (e.g., the device 100A, devices 100B, 200, or 900 described below) in which one of a lower device or an upper device stacked thereover along the third direction is an active device and the other one of the lower device and the upper device is an inactive device. Specifically, only one of the lower device and the upper device includes an active (e.g., metal, conductive, etc.) gate structure and the other one of the lower device and the upper device includes an inactive gate structure, such as a dielectric gate structure, which may be alternatively referred to as an isolation structure, an isolation gate, etc. In this regard, such a CFET structure may be described as including an active device (e.g., the lower device or the upper device) and an inactive device (e.g., the upper device or the lower device) stacked one over another along the third direction.

In some embodiments, referring to FIG. 1, the device 100A is configured with the lower device 110L being an inactive device having a dielectric gate structure 183L in place of an active gate structure and the upper device 110U being an active device having an active gate structure 182U (e.g., upper metal gate structure 982U described below) stacked over the lower device 110L. In the present disclosure, the dielectric gate structure 183L (e.g., third isolation structure 1102 described below) is alternatively referred to as the isolation structure 183L or the inactive gate structure 183L. In the present embodiments, the active gate structure 182U is hereafter referred to as the metal gate structure 182U to differentiate from the dielectric gate structure 183L. Details of the lower device 110L and the upper device 110U are described in view of FIGS. 1, 2, and 3, where FIG. 2 illustrates a schematic cross-sectional view of the device 100A taken along line AA′ of FIG. 1 and FIG. 3 illustrates a schematic cross-sectional view of the device 100A taken along line BB′ of FIG. 1.

In some embodiments, the upper device 110U includes a multi-channel structure of nanosheets 126′U surrounded by the metal gate structure 182U. The multi-channel structure may include a nanosheet structure (e.g., a nanosheet transistor), a nanowire structure (e.g., a nanowire transistor), a nanorod structure (e.g., a nanorod transistor), or the like. In the example configuration depicted herein, the upper device 110U includes a nanosheet structure. Referring to FIGS. 1-3, the upper device 110U includes the metal gate structure 182U wrapping around the multi-channel structure and a pair of source/drain features 162U (e.g., upper source/drain features 962U described below) disposed on opposite sides of the metal gate structure 182U along the first direction. The metal gate structure 182U extends, or is elongated, along the second direction. The number of the nanosheets 126′U in the multi-channel structure is at least one.

The nanosheets 126′U are configured to extend between, thereby connecting, the source/drain features 162U along the first direction. The nanosheets 126′U may be alternatively referred to as semiconductor layer 126′U (e.g., second semiconductor layer 926′U described below). In the example configuration in FIG. 2, the upper device 110U includes two nanosheets 126′U. Other numbers of nanosheets per device are within the scopes of various embodiments. The nanosheets 126′U include a suitable semiconductor material, such as Si, SiGe, or the like, configured as channels of the upper device 110U. In the present embodiments, the nanosheets 126′U include Si. In some embodiments, the nanosheets 126′U are formed as portions of a multilayer structure (e.g., multilayer structure 922′ described below) over the substrate.

The metal gate structure 182U includes a gate dielectric layer 178 (e.g., gate dielectric layer 978 described below) and a gate electrode 180U (e.g., gate electrode 980 described below) disposed over the gate dielectric layer 178, where the gate dielectric layer 178 extends or wraps around each of the nanosheets 126′U, and electrically isolating the gate electrode 180U from the nanosheets 126′U. The metal gate structure 182U extends around the gate dielectric layer 178 and nanosheets 126′U in a configuration referred to as a gate-all-around (GAA) configuration. In some embodiments, the metal gate structure 182U is said to interleave with the nanosheets 126′U to form the GAA configuration. Other gate configurations are within the scopes of various embodiments.

In some embodiments, referring to FIGS. 2 and 3, the gate dielectric layer 178 includes silicon oxide (SiO₂), a high-k dielectric material, the like, or combinations thereof. The high-k dielectric material may include a metal oxide or a silicate of Hf, Al, Zr, La, Mg, Ba, Ti, Pb, and combinations thereof. The gate electrode 180U is formed over and around the gate dielectric layers 178 and the nanosheets 126′U. The gate electrode 180U surrounds each of the nanosheets 126′U. In some embodiments, the gate electrode 180U includes polysilicon, Al, Cu, Ti, Ta, W, Co, Mo, nickel silicide, cobalt silicide, TaN, TiN, WN, WCN, TiAl, TiTaN, TiAlN, TaN, TaCN, TaC, TaSiN, metal alloys, the like, or combinations thereof. In some embodiments, the gate electrode material includes one or more work function metals.

The lower device 110L includes the dielectric gate structure 183L and source/drain features 162L (e.g., lower source/drain features 962 described below) disposed on opposite sides of the dielectric gate structure 183L. The dielectric gate structure 183L and the source/drain features 162L are vertically aligned with the metal gate structure 182U and the source/drain features 162U, respectively. Sated differently, the dielectric gate structure 183L and the source/drain features 162L correspondingly overlap the metal gate structure 182U, the source/drain features 162U, respectively, along the third direction.

In the present embodiments, the dielectric gate structure 183L is provided in place of a metal gate structure interleaved with a stack of nanosheets configured as the channel region between the source/drain features 162L. The dielectric gate structure 183L may include any suitable dielectric material. For example, the dielectric gate structure 183L may include an oxide-containing or a nitride containing dielectric material. Example dielectric materials include SiO₂, silicon nitride (SiN), silicon oxynitride (SiON), silicon carbide (SiC), silicon oxycarbonitride (SiOCN), silicon carbonitride (SiCN), the like, or combinations thereof. In some embodiments, the dielectric gate structure 183L includes one dielectric material layer. In some embodiments, the dielectric gate structure 183L includes multiple dielectric material layers. As will be described in detail below, the dielectric gate structure 183L may be formed concurrently with isolation structures configured to truncate the active regions (or fins) of the device 100A.

In some embodiments, referring to FIGS. 1 and 2, the source/drain features 162U, 162L include epitaxy structures and may thus be sometimes referred to as source/drain epitaxy structures 162U, 162L. In the present embodiments, the source/drain features 162U, 162L are formed on opposite sides of their corresponding gate structures along the first direction.

In some embodiments, the upper device 110U and the lower device 110L include source/drain features of different conductivity types. In one such example, the upper device 110U includes source/drain features 162U configured as of n-type conductivity (e.g., including silicon (Si) or silicon-carbon (Si—C) doped with a n-type dopant) and the lower device 110L includes source/drain features 162L configured as of p-type conductivity (e.g., including silicon germanium (SiGe) doped with a p-type dopant). As such, the upper device 110U, being the active device of the device 100A, is configured as a NMOS device. In another such example, the source/drain features 162U are configured as of p-type conductivity and the source/drain features 162L are configured as of n-type conductivity, rendering the upper device 110U to be a PMOS device. In some embodiments, the source/drain features 162U, 162L are configured with dopants of the same conductivity type, such as both are of n-type or both are of p-type. Example n-type dopants include phosphorus (P), arsenic (As), antimony (Sb), the like, or combinations thereof, and example p-type dopants include boron (B), aluminum (Al), indium (In), and gallium (Ga), the like, or combinations thereof.

In some embodiments, the device 100A further includes isolation structures 172 disposed between each one of the source/drain features 162U and the corresponding source/drain features 162L along the third direction, such that the isolation structure 172 electrically isolates the source/drain features of the upper device 110U from those of the lower device 110L. In this regard, the isolation structures 172 are alternatively referred to as source/drain isolation structures 172. In some embodiments, referring to FIG. 2, each sidewall of the dielectric gate structure 183L extends past a bottom surface of the source/drain feature 162U along the third direction such that the sidewall of the source/drain feature 162U also partially overlaps or interfaces a sidewall of the corresponding isolation structure 172.

In some embodiments, though not depicted separately, the isolation structure 172 includes multiple layers, such as a liner (e.g., liner 963 described below) and a dielectric layer (e.g., dielectric layer 968 described below) disposed over the liner. The liner, also referred to as a contact etch-stop layer (CESL), may include SiN and may be formed as a U-shaped conformal layer over the source/drain features 162L. The dielectric layer may include a suitable dielectric or insulating material, such as SiO₂, a SiO₂-based dielectric material, and/or the like. In some examples, the dielectric layer may have a composition similar to that of the dielectric gate structure 183L. In the present embodiments, the source/drain features 162U are formed over, and in direct contact with, upper surfaces of the isolation structures 172, i.e., the liner and the dielectric layer.

Referring to FIGS. 1-3, the multilayer structure 110 further includes an intermediate layer 156 (e.g., intermediate layer 990 described below) disposed between the dielectric gate structure 183L and metal gate structure 182U along the third direction. In other words, the dielectric gate structure 183L and metal gate structure 182U are separated by the intermediate layer 156 along the third direction. In some embodiments, the intermediate layer 156 includes a dielectric layer (e.g., inner isolation structure 956 described below) and is configured as a vertical gate isolation structure electrically isolating the dielectric gate structure 183L from the metal gate structure 182U, in a configuration referred to as an isolated gate configuration, providing independent control of the dielectric gate structure 183L and metal gate structure 182U. In this regard, the intermediate layer 156 is alternatively referred to as the isolation structure 156. In some embodiments, referring to FIGS. 2 and 3, the intermediate layer 156 is aligned with the nanosheets 126′U along the third direction, i.e., sidewalls of the intermediate layer 156 are aligned with sidewalls of the nanosheets 126′U in the cross-sectional views of the device 100A.

In some embodiments, though not depicted separately, the intermediate layer 156 may further include at least two middle second semiconductor layers (e.g., second semiconductor layers 926′M described below), each one of which is disposed between the dielectric layer and each of the metal gate structure 182U and the dielectric gate structure 183L along the third direction. As such, the dielectric layer is interposed between the two middle semiconductor layers along the third direction. The middle second semiconductor layers may be configured as dummy semiconductor layers (i.e., dummy channel) and may have substantially the same composition as the nanosheets 126′U and may be formed during the same operation(s) as the nanosheets 126′U.

As can be seen in the CFET structures provided herein, such as the device 100A, the stacking of one device over another device saves about 50% of the required chip area, compared to other approaches without stacking of semiconductor devices. In some embodiments, it is possible to manufacturing an IC device comprising multiple device stacks by CFET processes, with little or no changes to the manufacturing processes.

In some embodiments, though not depicted in FIGS. 1-3, the device 100A further includes isolation structures (e.g., isolation structures 932 described below) disposed over the substrate and in trenches (not depicted) between adjacent fins 128. The isolation structures adjacent to the fins 128 may include SiO₂, SiN, a low-k dielectric material (tetraethylorthosilicate (TEOS) oxide, un-doped silicate glass, or doped silicon oxide such as borophosphosilicate glass (BPSG), FSG, phosphosilicate glass (PSG), boron doped silicon glass (BSG), etc.), the like, or combinations thereof. In some embodiments, the isolation structures surround bottom portions of the fin 128 and are in direct contact with an upper surface of the substrate.

Still referring to FIG. 2, the device 100A further includes inner spacers 154M disposed at end portions of the metal gate structure 182U and between each source/drain feature 162U and the metal gate structure 182U. Similarly, the device 100A includes inner spacers 154D disposed at end portions of the dielectric gate structure 183L and between each source/drain feature 162L and the dielectric gate structure 183L. In the depicted embodiment, the inner spacers 154M, 154D are aligned and spaced apart from one another along the third direction. In some embodiments, each of the inner spacers 154D is surrounded by the dielectric gate structure 183L in the cross-sectional view depicted in FIG. 2. In some embodiments, each of the inner spacers 154D is embedded and fully enclosed within the dielectric gate structure 183L.

The inner spacers 154M, 154D may be configured to have substantially the same composition and structure and may be collectively referred to as the inner spacers 154 (e.g., inner spacers 954 described below). The inner spacers 154 may include any suitable dielectric material, such as SiO₂, SiN, SiC, SiOC, SION, SiCN, SiOCN, the like, or combinations thereof. In some embodiments, the inner spacers 154 include multiple layers.

Referring to FIGS. 1 and 3, the device 100A further includes gate isolation structures 186 extending lengthwise along the first direction, i.e., parallel to the fin 128. The gate isolation structure 186 is configured to cut or truncate the metal gate structure 182U and the dielectric gate structure 183L and may therefore be alternatively referred to as a gate cut feature 186. In the present embodiments, two gate isolation structures 186 are depicted as sandwiching the fin 128 therebetween. In some embodiments, referring to FIG. 1, the gate isolation structure 186 directly contacts a sidewall of each of the source/drain features 162U, 162L. In some embodiments, referring to FIG. 3, the gate isolation structure 186 directly contacts sidewalls of both the metal gate structure 182U and the dielectric gate structure 183L. Furthermore, portions of the gate electrode 180U are disposed between each nanosheet 126′U and an adjacent one of the gate isolation structures 186 along the second direction such that the gate electrode 180U wraps around each nanosheet 126′U.

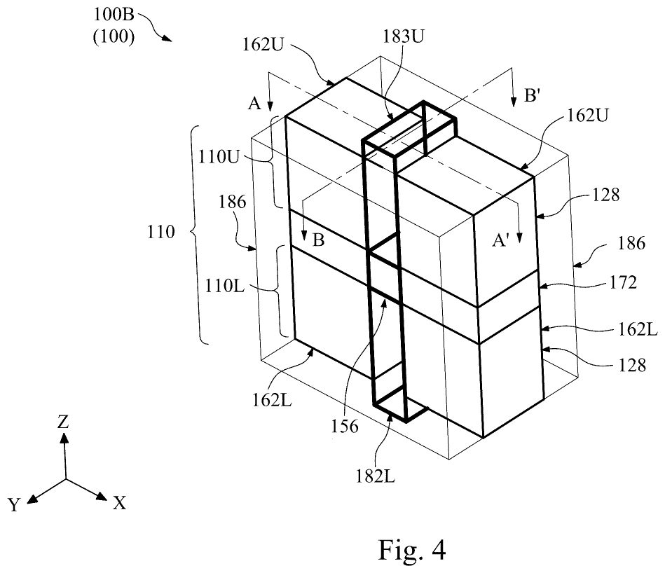

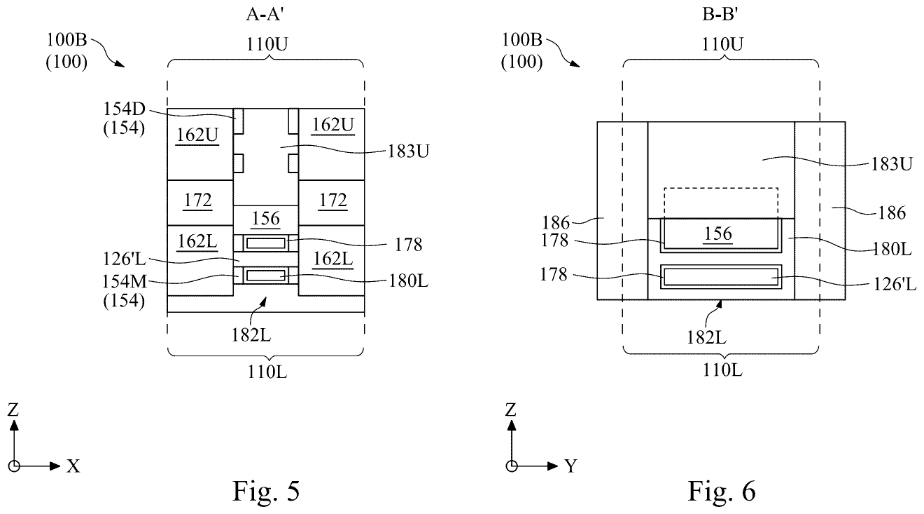

FIGS. 4, 5, and 6 illustrate schematic views of an embodiment of a semiconductor device 100B (hereafter referred to as device 100B), in portion or in entirety, according to some embodiments of the present disclosure. FIG. 4 illustrates a schematic perspective view of the device 100B; FIG. 5 illustrates a schematic cross-sectional view of the device 100B along line AA′ of FIG. 4; and FIG. 6 illustrates a schematic cross-sectional view of the device 100B along line BB′ of FIG. 4.

In the present embodiments, as the device 100B is substantially similar to or the same as the device 100A in structure in some aspects, components common to both devices are depicted using the same reference numerals and their descriptions are omitted below for purposes of simplicity. However, the device 100B also differs from the device 100A in some other aspects.

For example, still referring to FIGS. 4-6, the upper device 110U of the device 100B is configured as an inactive device having a dielectric gate structure 183U in place of an active gate structure, while the lower device 110L of the device 100B is configured as an active device having an active (or metal) gate structure 182L (e.g., lower metal gate structure 982L described below) extending from the dielectric gate structure 183U (e.g., third isolation structure 1102 described below) along the third direction. In this regard, the lower device 110L includes a multi-channel structure of nanosheets 126′L surrounded by a metal gate structure 182L. The structure and composition of each of the nanosheets 126′L is substantially similar to or the same as that of the nanosheet 126′U, and the number of the nanosheets 126′L in the multi-channel structure of the lower device 110L is at least one, such as two in the depicted embodiment. The structure and composition of the metal gate structure 182L is substantially similar to or the same as that of the metal gate structure 182U and the structure and composition of the dielectric gate structure 183U is substantially similar to or the same as that of the dielectric gate structure 183L as described above. The metal gate structure 182L and the dielectric gate structure 183U are separated by the intermediate layer 156, which is described in detail above with respect to the device 100A. Furthermore, referring to FIG. 5, the dielectric gate structure 183U is disposed between and separated from the source/drain features 162U by the inner spacers 154D, and the metal gate structure 182L is disposed between and separated from the source/drain features 162L by the inner spacers 154M, where the source/drain features 162U, 162L and the inner spacers 154D, 154M are also described in detail above with respect to the device 100A.

In the present disclosure, the devices 100A and 100B may be collectively referred to as device 100 having a CFET structure configured with two devices stacked one over another along a vertical direction. One of the two devices is configured as an active device having an active gate structure (or a metal gate structure; e.g., the metal gate structure 182U/182L) and the other one of the two devices is configured as an inactive device having an inactive gate structure (or a dielectric gate structure; e.g., the dielectric gate structure 183L/183U). In some embodiments, such as in the case of the device 100A, the active device may be the upper device (e.g., the upper device 110U) and the inactive device may be the lower device (e.g., the lower device 110L). In some embodiments, such as in the case of the device 100B, the active device may be the lower device (e.g., the lower device 110L) and the inactive device may be the upper device (e.g., the upper device 110U). The active device and the inactive device may be configured to have different conductivity types. The device 100 generally includes an intermediate layer (e.g., the intermediate layer 156) that electrically isolate the active gate structure from the inactive gate structure along the third (vertical) direction.

As the inactive device and the active device may be configured with source/drain features (e.g., the source/drain features 162U, 162L) of different conductivity types, embodiments of the present disclosure provide means for adjusting device performance to compensate or otherwise adjust for differences in current levels measured in NMOS devices and PMOS devices. For example, by configuring a NMOS device to be inactive (i.e., replacing an active gate structure with an inactive gate structure in the NMOS device) and configuring the complementary PMOS device, which is stacked over or below the NMOS device in a CFET inverter, to remain active, a speed of the NMOS device can be reduced to match a speed of the PMOS device.

Advantageously, embodiments provided herein allow the performance of the NMOS device and the complementary PMOS device in a CFET structure to be “skewed” without altering dimensions of NMOS/PMOS channels. For example, if the inactive device is configured as a NMOS device (i.e., including source/drain features of n-type conductivity), then the CFET structure is considered to include a skewed PMOS device. Conversely, if the inactive device is configured as a PMOS device (i.e., including source/drain features of p-type conductivity), then the CFET structure is considered to include a skewed NMOS device. In addition, by replacing one of the metal gate structures (e.g., the metal gate structure of the NMOS device or of the PMOS device) in the CFET structure with a dielectric gate structure, the number of conductors (e.g., the metal gate structure and any contact or interconnect features electrically coupled thereto) may be reduced, leading to lowered capacitance and improved overall performance of the device.

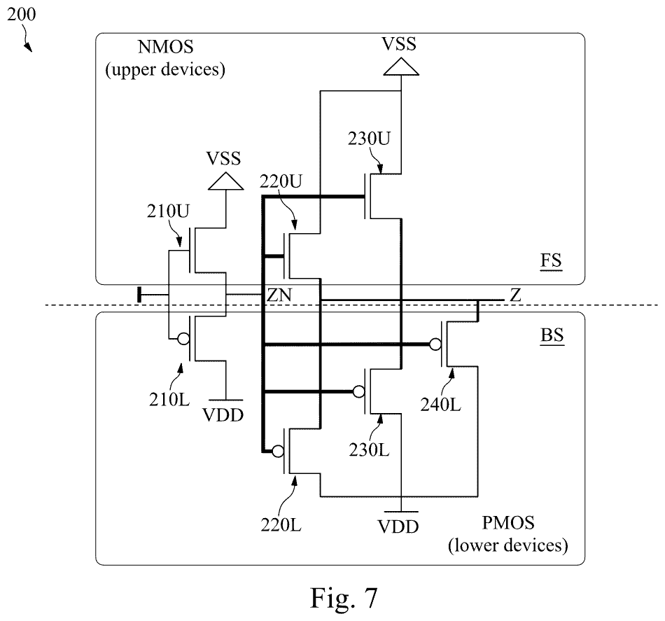

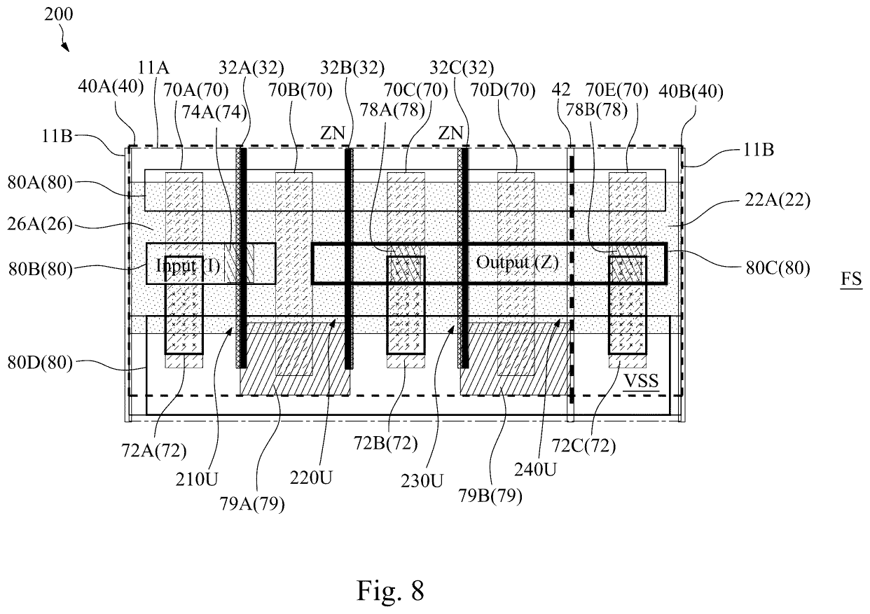

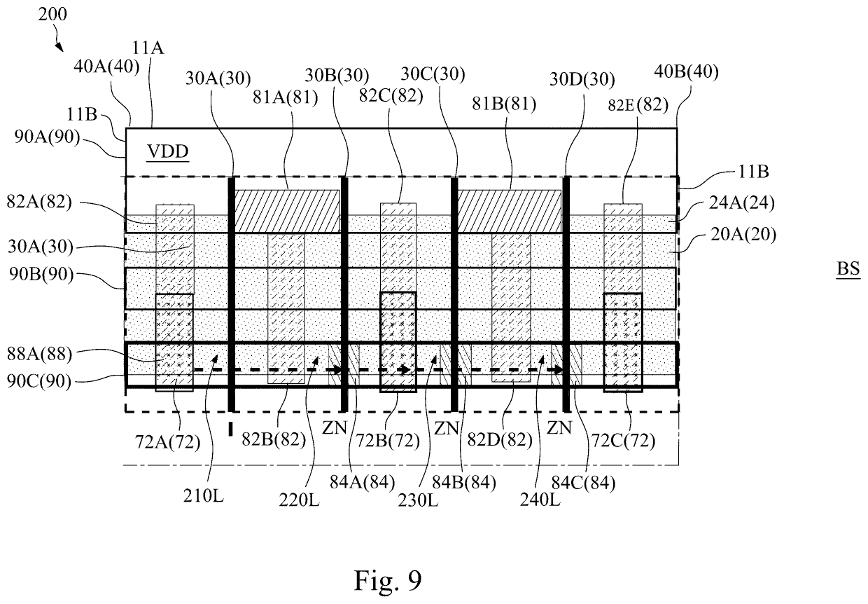

In some embodiments, such as the embodiment described in reference to FIGS. 7, 8, and 9, such advantages associated with the device 100 may be realized in a device (e.g., device 200) in which multiple CFET structures are present. FIG. 7 illustrates a circuit block diagram of a device 200, in portion or in entirety, that includes components analogous to those of the device 100B. An example layout diagram of a frontside FS of the device 200 is illustrated in FIG. 8, and an example layout diagram of a backside BS of the device 200 is illustrated in FIG. 9. In the depicted embodiment, the device 200 may be configured as a cell including a logic device (e.g., a buffer cell, NAND logic gate, NOR logic gate, etc.). Embodiments of the present disclosure may also be applicable to cells including a memory (e.g., a static random-access memory (SRAM) device.

Referring to FIGS. 7 and 8 collectively, the device 200 includes a first upper device 210U, a second upper device 220U, a third upper device 230U, and a fourth upper device 240U provided or formed on the frontside FS. Referring to FIGS. 7 and 9 collectively, the device 200 includes a first lower device 210L, a second lower device 220L, a third lower device 230L, and a fourth lower device 240L provided or formed on the backside BS and corresponding to the upper devices 210U, 220U, 230U, and 240U, respectively. Specifically, the upper devices 210U, 220U, 230U and lower devices 210L, 220L, 230L, 240L are configured as active devices, and the fourth upper device 240U is configured as an inactive device similar to the upper device 110U of the device 100B.

During device operation, referring to FIGS. 7-9 collectively, an input signal I may be provided to a first CFET structure (e.g., a CFET inverter) that includes the first upper device 210U and the first lower device 210L through a gate contact (e.g., gate contact 74A described below) on the frontside FS, where an output signal ZN of the first inverter is subsequently provided to a backside metal line (e.g., backside metal line 90C described below) through an inter-device source/drain contact (e.g., inter-device source/drain contact 72A described below) within the first inverter and then through a backside source/drain contact (e.g., backside source/drain contact 82A described below). Subsequently, the output signal ZN may be provided as an input signal to each of three remaining CFET structures in the device 200 from the backside BS via the backside metal line and backside gate contacts (e.g., backside gate contacts 84A, 84B, and 84C, respectively, described below) to the corresponding lower devices 220L, 230L, 240L. This arrangement is different from existing devices having CFET structures in which the input signal I is provided to each of the CFET structures from the frontside FS (i.e., to the upper devices 220U, 230U, and 240U, where the upper device 240U is configured as an active device) and not from the backside BS.

As the upper device 240U is an inactive device, an overall output Z of the device 200 is then provided from the upper devices 220U, 230U to a frontside metal line (e.g., frontside metal line 80C described below) through corresponding frontside source/drain contacts (e.g., frontside via contacts 78A, 78B described below). In the depicted embodiment, VSS (e.g., ground) is coupled to the upper devices 220U, 230U on the frontside FS, while VDD (e.g., supply voltage) is coupled to the lower devices 220L, 230L, 240L on the backside BS.

Details of the device 200 are described in reference to the layout diagrams of FIGS. 8 and 9. For purposes of simplicity, certain components of the device 200, such as a substrate, isolation structures between adjacent active regions, interlayer dielectric (ILD) layers, etc., are omitted in FIGS. 8 and 9 and their corresponding descriptions below.

Referring to FIG. 8, when viewed from the frontside FS, the device 200 includes at least one upper active region 22A (alternatively referred to as an upper fin 22A) extending along the first direction, and additional upper active regions (collectively referred to as upper active regions 22) are spaced apart along the second direction. The device 200 further includes a plurality of metal gate structures 32A, 32B, 32C (collectively referred to as metal gate structures 32) each extending along the second direction and spaced apart along the first direction. Each metal gate structures 32A, 32B, 32C engages various channel regions of the upper active region 22A to form the upper devices 210U, 220U, 230U that are active devices, respectively, where each channel region thereof includes a plurality of nanosheets (alternatively referred to as semiconductor layers) stacked along the third direction and wrapped around by the corresponding metal gate structures. The device 200 further includes a dielectric gate structure 42 that is spaced from the metal gate structure 32C along the second direction and extends vertically from metal gate structure 30D (of the lower device 240L) along the third direction. The dielectric gate structure 42 engages the upper active region 22A to form the upper device 240U, which is an inactive device. In the depicted embodiment, the upper devices 210U, 220U, 230U, 240U are configured to have the same conductivity type, such as n-type, though the present disclosure does not limit the upper devices to any particular conductivity type.

Referring to FIG. 9, when viewed from the backside BS, the device 200 includes at least one lower active region 20A (alternatively referred to as a lower fin 20A) extending along the first direction, and additional lower active regions (collectively referred to as lower active regions 20) are spaced apart along the second direction. The device 200 includes a plurality of metal gate structures 30A, 30B, 30C, and 30D (collectively referred to as metal gate structures 30) each extending along the second direction and spaced apart along the first direction. Each metal gate structure 30 engages various channel regions of the lower active region 20A to form the lower devices 210L, 220L, 230L, 240L that are active devices, where each channel region includes a plurality of semiconductor nanosheets stacked along the vertical direction and wrapped around by the corresponding metal gate structures. In the depicted embodiment, the lower devices 210L, 220L, 230L, 240L are configured to have the same conductivity type, such as p-type, which is different from that of the upper devices 210U, 220U, 230U, 240U, though the present disclosure does not limit the each of the upper devices and lower devices to any particular conductivity type.

As such, in the depicted embodiments, the upper active region 22A may correspond to the upper one of the fins 128, the lower active region 20A may correspond to the lower one of the fins 128, the nanosheets in each of the channel regions may correspond to nanosheets 126′U, 126′L, the dielectric gate structure 42 may correspond to the dielectric gate structure 183U, and the metal gate structure 30D may correspond to the metal gate structure 182L, as described above with respect to the device 100B.

Referring to FIG. 8, the device 200 includes a plurality of source/drain features 26 (e.g., 26A) adjacent to each metal gate structure 32 (i.e., adjacent to the stack of nanosheets in the upper active region 22). For example, the source/drain features 26A are formed adjacent to the stack of nanosheets in the upper active region 22A. Analogously, referring to FIG. 9, the device 200 includes a plurality of source/drain features 24 (e.g., 24A) adjacent to each metal gate structure 30 (i.e., adjacent to the stack of nanosheets in the lower active region 20). For example, the source/drain features 24A are formed adjacent to the stack of nanosheets in the lower active region 20A. For embodiments in which the upper devices 210U, 220U, 230U, 240U are configured as NMOS devices and the lower devices 210L, 220L, 230L, 240L are configured as PMOS devices, the source/drain features 26 may include Si or silicon-carbon (Si—C) doped with a n-type dopant described herein, and the source/drain features 24 may include SiGe doped with a p-type dopant described herein.

Referring to FIG. 8 again, the device 200 includes a plurality of frontside source/drain contacts 70A, 70B, 70C, 70D, 70E (collectively referred to as frontside source/drain contacts 70) each extending along the second direction and disposed between two adjacent metal gate structures 32 along the first direction. Each frontside source/drain contact 70 may be continuous across multiple upper active regions 22 or across a single upper active region 22 along the second direction. Each frontside source/drain contact 70 is electrically coupled to a source/drain feature 26.

In some embodiments, the device 200 further includes inter-device source/drain contacts 72A, 72B, and 72C (collectively referred to as inter-device source/drain contacts 72) each electrically coupling one of the frontside source/drain contacts 70 to a corresponding backside source/drain contact 82 (e.g., one of backside source/drain contacts 82A, 92B, 82C, 82D, 82E). The device 200 further includes at least one gate contact 74A extending vertically along the third direction and electrically coupling one of the metal gate structures 32 to the frontside interconnect structures (e.g., one of the frontside metal lines 80).

Furthermore, still referring to FIG. 8, the device 200 may include a plurality of frontside interconnect structures electrically coupled to the contact structures described herein. For example, the device 200 includes a plurality of frontside via contacts 78A, 78B (collectively referred to as frontside via contacts 78). The frontside via contacts 78 each extending vertically along the third direction and electrically couple a contact structures (e.g., the frontside source/drain contacts 70) to one of the frontside metal lines 80A, 80B, 80C, 80D (collectively referred to as frontside metal lines 80). In the depicted embodiment, the frontside metal line 80B provides the input signal I; the frontside metal line 80C receives the overall output signal Z; and the frontside metal line 80D is configured as the VSS. The frontside metal lines 80 may be alternatively referred to as M0 metal lines as they are disposed in a metallization layer M0 closest to the frontside of the substrate of the device 200. The device 200 may further include frontside power via contacts 79A and 79B (collectively referred to as frontside power via contacts 79) each electrically coupling one of the frontside source/drain contacts 70 to the VSS.

When viewed from the backside BS, referring to FIG. 9, the device 200 further includes a plurality of backside source/drain contacts 82A, 82B, 82C, 82D, 82E (collectively referred to as frontside source/drain contacts 82) and electrically coupled to one of the source/drain features 24. The device 200 includes a plurality of backside gate contacts 84A, 84B, 84C (collectively referred to as backside gate contacts 84). The device 200 further includes at least one backside via contact 88A electrically coupling one of the backside source/drain contacts 82 to one of backside metal lines (e.g., backside metal line 90C). The device 200 may further include backside power via contacts 81A and 81B (collectively referred to as backside power via contacts 81) each electrically coupling one of the backside source/drain contacts 82 to the VDD.

Still further, the device 200 includes a plurality of backside metal lines 90A, 90B, 90C (collectively referred to as backside metal lines 90). The backside via contacts 88A electrically couples one of the backside source/drain contacts 82 to a corresponding one of the backside metal line 90, and the backside gate contacts 84 each electrically couple one of the metal gate structures 30 to one of the backside metal lines 90 (e.g., backside metal line 90C). In some embodiments, the backside metal line 90A is configured as the VDD.

In various embodiments, each of the frontside/backside source/drain contacts 70/82, the inter-device source/drain contacts 72, the frontside/backside gate contacts 74/84, the frontside/backside via contacts 78/88A, and the frontside/backside metal lines 80/90 include a conductive material, such as tungsten (W), copper (Cu), cobalt (Co), ruthenium (Ru), aluminum (Al), titanium (Ti), tantalum (Ta), platinum (Pt), the like, or combinations (or alloys) thereof. In some embodiments, a barrier layer having TiN, TaN, or the like, a silicide layer having a metal silicide material such as NiSi, other suitable materials, or combinations thereof, may be included in one or more of the aforementioned contact structures, interconnect structures, and metal lines.

Furthermore, though omitted herein for purposes of simplicity, each of the aforementioned contact structures, interconnect structures, and metal lines may be formed or embedded in a dielectric layer that includes one or more of an ILD layer, a contact etch stop layer (CESL), the like, or combinations thereof, configured to electrically isolate the aforementioned structures from the surrounding conductive components.

As described herein, still referring to FIGS. 8 and 9, active region isolation structures 40 (e.g., active region isolation structures 40A, 40B) each extend along the second direction and truncate the active regions 20 and 22 into separate portions, thereby defining a vertical cell boundary 11B of the device 200. Each vertical cell boundary 11B is perpendicular to a horizontal cell boundary 11A. In some embodiments, each active region isolation structure 40 is configured to prevent or otherwise reduce shorting between neighboring devices.

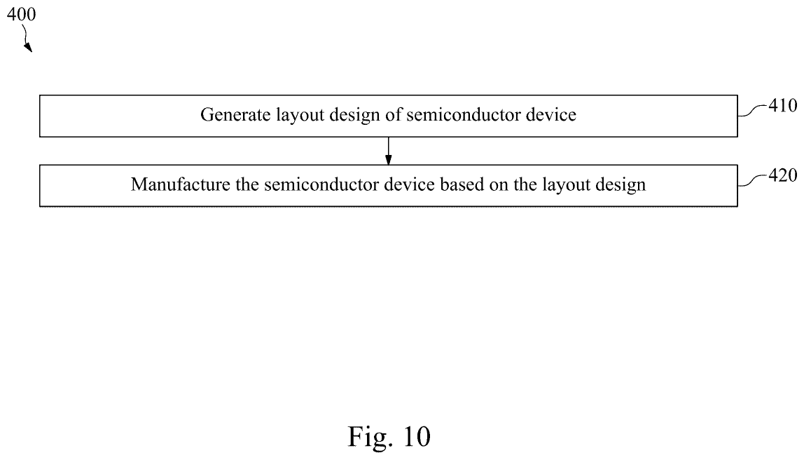

FIG. 10 is a flowchart of a method 400 of forming or manufacturing a semiconductor device, such as any of the semiconductor devices 100A-100C, in portion or in entirety, in accordance with some embodiments. It is understood that additional operations may be performed before, during, and/or after the method 400 depicted in FIG. 10.

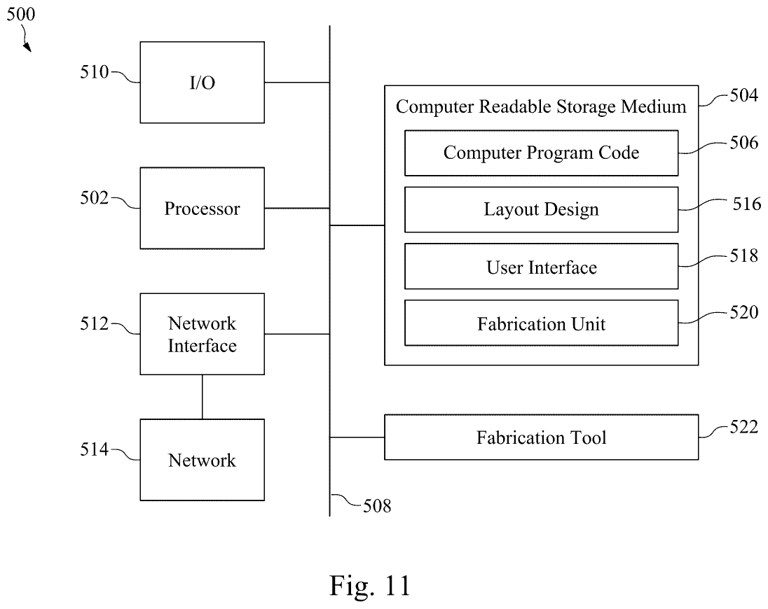

In operation 410 of the method 400, a layout design of a semiconductor device is generated. The operation 410 is performed by a processing device (e.g., processor 502 of FIG. 11) configured to execute instructions for generating a layout design. In one approach, the layout design is generated by placing layout designs of one or more standard cells through a user interface. In one approach, the layout design is automatically generated by a processor executing a synthesis tool that converts a logic design (e.g., Verilog) into a corresponding layout design. In some embodiments, the layout design is rendered in a graphic database system (GDSII) file format. In some embodiments, the layout design includes one that is similar to any of the example layouts depicted in FIGS. 8 and 9, each depicting an embodiment of the semiconductor device 100C described herein.

In operation 420 of the method 400, a semiconductor device is manufactured based on the layout design. In some embodiments, the operation 420 of the method 400 includes manufacturing at least one mask based on the layout design, and manufacturing a semiconductor device based on the at least one mask. Example manufacturing operations of the operation 420 may include patterning, implantation, deposition, etching, planarization, the like, or combinations thereof, to form a plurality of front-end-of-line device features (e.g., the active regions 20/22, the source/drain features 24/26, the metal gate structures 30/32, the active region isolation structures 40, etc.), device-level (or middle-end-of-line) contacts (e.g., the frontside/backside source/drain contacts 70/82, the inter-device source/drain contacts 72, etc.), interconnect structures (or back-end-of-line structures; e.g., the frontside/backside via contacts 78/88A, etc.), and metal lines (or back-end-of-line structures; e.g., the frontside/backside metal lines 80/90, etc.).

In some embodiments, the method 400 is implemented as a standalone software application for execution by a processor. In some embodiments, the method 400 is implemented as a software application that is a part of an additional software application. In some embodiments, the method 400 is implemented as a plug-in to a software application. In some embodiments, the method 400 is implemented as a software application that is a portion of an EDA tool. In some embodiments, the method 400 is implemented as a software application that is used by an EDA tool. In some embodiments, the EDA tool is used to generate a layout design of the integrated circuit device. In some embodiments, the layout design is stored on a non-transitory computer readable medium. In some embodiments, the layout design is generated based on a netlist which is created based on the schematic design.

FIG. 11 is a schematic view of a system 500 for designing and manufacturing an IC layout design, in accordance with some embodiments. The system 500 generates or places one or more IC layout designs, as described herein. In some embodiments, the system 500 manufactures one or more semiconductor devices based on the one or more IC layout designs, as described herein. The system 500 includes a (e.g., hardware) processor 502 and a non-transitory, computer readable storage medium 504 encoded with, e.g., storing, computer program code 506, e.g., a set of executable instructions. The computer readable storage medium 504 is configured to interface with manufacturing machines for producing the semiconductor device. The processor 502 is electrically coupled to the computer readable storage medium 504 by a bus 508. The processor 502 is also electrically coupled to an I/O interface 510 by the bus 508. A network interface 512 is also electrically connected to the processor 502 by the bus 508. Network interface 512 is connected to a network 514, so that the processor 502 and the computer readable storage medium 1504 can connect to external elements via network 514. The processor 502 is configured to execute the computer program code 506 encoded in the computer readable storage medium 504 to cause the system 500 to be usable for performing a portion or all of the operations as described in method 400.

In some embodiments, the processor 502 is a central processing unit (CPU), a multi-processor, a distributed processing system, an application specific integrated circuit (ASIC), and/or a suitable processing unit. In some embodiments, the computer readable storage medium 504 is an electronic, magnetic, optical, electromagnetic, infrared, and/or a semiconductor system (or apparatus or device). For example, the computer readable storage medium 504 includes a semiconductor or solid-state memory, a magnetic tape, a removable computer diskette, a random-access memory (RAM), a read-only memory (ROM), a rigid magnetic disk, and/or an optical disk. In some embodiments using optical disks, the computer readable storage medium 504 includes a compact disk-read only memory (CD-ROM), a compact disk-read/write (CD-R/W), and/or a digital video disc (DVD).

In some embodiments, the computer readable storage medium 504 stores the computer program code 506 configured to cause the system 500 to perform the method 400. In some embodiments, the computer readable storage medium 504 also stores information needed for performing the method 400 as well as information generated during the performance of the method 400, such as layout design 516, user interface 518, fabrication unit 520, and/or a set of executable instructions to perform the operation of method 400.

In some embodiments, the computer readable storage medium 504 stores instructions (e.g., the computer program code 506) for interfacing with manufacturing machines. The instructions (e.g., the computer program code 506) enable the processor 502 to generate manufacturing instructions readable by the manufacturing machines to effectively implement the method 400 during a manufacturing process.

The system 500 includes the I/O interface 510. The I/O interface 510 is coupled to external circuitry. In some embodiments, the I/O interface 510 includes a keyboard, keypad, mouse, trackball, trackpad, and/or cursor direction keys for communicating information and commands to the processor 502.

The system 500 also includes the network interface 512 coupled to the processor 502. The network interface 512 allows the system 1500 to communicate with the network 514, to which one or more other computer systems are connected. The network interface 512 includes wireless network interfaces such as BLUETOOTH, WIFI, WIMAX, GPRS, or WCDMA; or wired network interface such as ETHERNET, USB, or IEEE-13154. In some embodiments, the method 400 is implemented in two or more systems 500, and information such as layout design, user interface and fabrication unit are exchanged between different systems 500 by the network 514.

The system 500 is configured to receive information related to a layout design through the I/O interface 510 or network interface 512. The information is transferred to the processor 502 by the bus 508 to determine a layout design for producing an IC. The layout design is then stored in the computer readable storage medium 504 as the layout design 516. The system 500 is configured to receive information related to a user interface through the I/O interface 510 or network interface 512. The information is stored in the computer readable storage medium 504 as the user interface 518. The system 500 is configured to receive information related to a fabrication unit through the I/O interface 510 or network interface 512. The information is stored in the computer readable storage medium 504 as the fabrication unit 520. In some embodiments, the fabrication unit 520 includes fabrication information utilized by the system 500.

In some embodiments, the method 400 is implemented by a manufacturing device to manufacture an integrated circuit using a set of masks manufactured based on one or more layout designs generated by the system 500. In some embodiments, the system 500 includes a manufacturing device (e.g., fabrication tool 522) to manufacture an integrated circuit using a set of masks manufactured based on one or more layout designs of the present disclosure. In some embodiments, the system 500 of FIG. 11 generates layout designs of an IC that are smaller than other approaches. In some embodiments, the system 500 of FIG. 11 generates layout designs of a semiconductor device that occupy less area than other approaches.

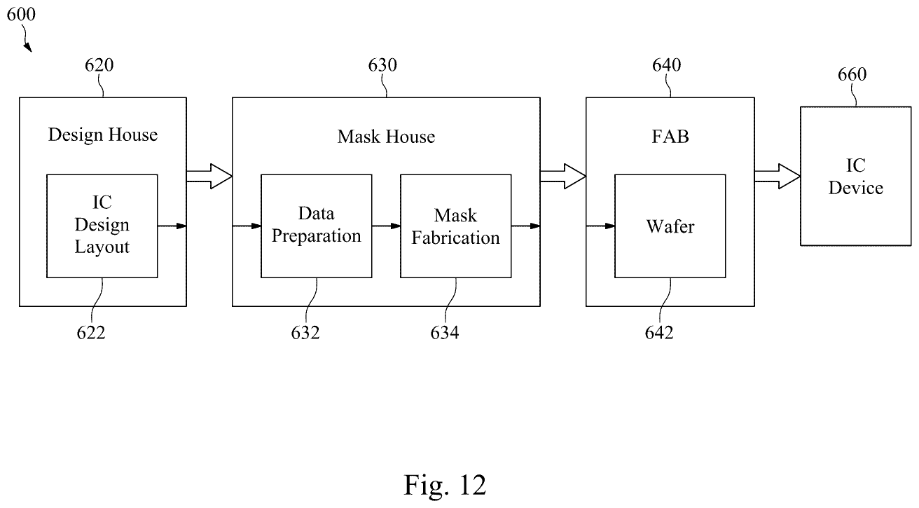

FIG. 12 is a block diagram of an integrated circuit (IC)/semiconductor device manufacturing system 600, and an IC manufacturing flow associated therewith, in accordance with at least one embodiment of the present disclosure.

In FIG. 12, the IC manufacturing system 600 includes entities, such as a design house 620, a mask house 630, and an IC manufacturer/fabricator (“fab”) 640, that interact with one another in the design, development, and manufacturing cycles and/or services related to manufacturing an IC device (semiconductor device) 660 (e.g., corresponding to any of the devices 100A, 100B, and 200). The entities in the IC manufacturing system 600 are connected by a communications network. In some embodiments, the communications network is a single network. In some embodiments, the communications network is a variety of different networks, such as an intranet and the Internet. The communications network includes wired and/or wireless communication channels. Each entity interacts with one or more of the other entities and provides services to and/or receives services from one or more of the other entities. In some embodiments, two or more of design house 620, mask house 630, and IC fab 640 is owned by a single company. In some embodiments, two or more of design house 620, mask house 630, and IC fab 640 coexist in a common facility and use common resources.

The design house (or design team) 620 generates an IC design layout 622. The IC design layout 622 includes various geometrical patterns designed for the IC device 660. The geometrical patterns correspond to patterns of metal, oxide, or semiconductor layers that make up the various components of the IC device 660 to be fabricated. The various layers combine to form various IC features. For example, a portion of the IC design layout 622 includes various IC features, such as an active region, gate structures, source/drain regions, interconnect structures, and openings for bonding pads, to be formed in a semiconductor substrate (such as a silicon wafer) and various material layers disposed on the semiconductor substrate. The design house 620 implements a proper design procedure to form the IC design layout 622. The design procedure includes one or more of logic design, physical design or place and route. The IC design layout 622 is presented in one or more data files having information of the geometrical patterns. For example, the IC design layout 622 can be expressed in a GDSII file format or DFII file format.

The mask house 630 includes mask data preparation 632 and mask fabrication 634. The mask house 630 uses the IC design layout 622 to manufacture one or more masks to be used for fabricating the various layers of the IC device 660 according to the IC design layout 622. The mask house 630 performs the mask data preparation 632, where the IC design layout 622 is translated into a representative data file (“RDF”). The mask data preparation 632 provides the RDF to the mask fabrication 634. The mask fabrication 634 includes a mask writer. A mask writer converts the RDF to an image on a substrate, such as a mask (reticle) or a semiconductor wafer. The design layout is manipulated by the mask data preparation 632 to comply with particular characteristics of the mask writer and/or requirements of the IC fab 640. In FIG. 12, the mask data preparation 632 and mask fabrication 634 are illustrated as separate elements. In some embodiments, the mask data preparation 632 and mask fabrication 634 can be collectively referred to as mask data preparation.

In some embodiments, the mask data preparation 632 includes optical proximity correction (OPC) which uses lithography enhancement techniques to compensate for image errors, such as those that can arise from diffraction, interference, other process effects and the like. OPC adjusts the IC design layout 622. In some embodiments, the mask data preparation 632 includes further resolution enhancement techniques (RET), such as off-axis illumination, sub-resolution assist features, phase-shifting masks, other suitable techniques, and the like or combinations thereof. In some embodiments, inverse lithography technology (ILT) is also used, which treats OPC as an inverse imaging problem.

In some embodiments, the mask data preparation 632 includes a mask rule checker (MRC) that checks the IC design layout that has undergone processes in OPC with a set of mask creation rules which contain certain geometric and/or connectivity restrictions to ensure sufficient margins, to account for variability in semiconductor manufacturing processes, and the like. In some embodiments, the MRC modifies the IC design layout to compensate for limitations during the mask fabrication 634, which may undo part of the modifications performed by OPC in order to meet mask creation rules.

In some embodiments, the mask data preparation 632 includes lithography process checking (LPC) that simulates processing that will be implemented by the IC fab 640 to fabricate the IC device 660. LPC simulates this processing based on the IC design layout 622 to create a simulated manufactured device, such as the IC device 660. The processing parameters in LPC simulation can include parameters associated with various processes of the IC manufacturing cycle, parameters associated with tools used for manufacturing the IC, and/or other aspects of the manufacturing process. LPC takes into account various factors, such as aerial image contrast, depth of focus (“DOF”), mask error enhancement factor (“MEEF”), other suitable factors, and the like or combinations thereof. In some embodiments, after a simulated manufactured device has been created by LPC, if the simulated device is not close enough in shape to satisfy design rules, OPC and/or MRC can be repeated to further refine the IC design layout 622.

It should be understood that the above description of the mask data preparation 632 has been simplified for the purposes of clarity. In some embodiments, the mask data preparation 632 includes additional features such as a logic operation (LOP) to modify the IC design layout according to manufacturing rules. Additionally, the processes applied to the IC design layout 622 during the mask data preparation 632 may be executed in a variety of different orders.

After the mask data preparation 632 and during mask fabrication 634, a mask or a group of masks are fabricated based on the modified IC design layout. In some embodiments, an electron-beam (e-beam) or a mechanism of multiple e-beams is used to form a pattern on a mask (photomask or reticle) based on the modified IC design layout. The mask can be formed in various technologies. In some embodiments, the mask is formed using binary technology. In some embodiments, a mask pattern includes opaque regions and transparent regions. A radiation beam, such as an ultraviolet (UV) beam, used to expose the image sensitive material layer (e.g., photoresist) which has been coated on a wafer, is blocked by the opaque region and transmits through the transparent regions. In one example, a binary mask includes a transparent substrate (e.g., fused quartz) and an opaque material (e.g., chromium) coated in the opaque regions of the mask. In another example, the mask is formed using a phase shift technology. In the phase shift mask (PSM), various features in the pattern formed on the mask are configured to have proper phase difference to enhance the resolution and imaging quality. In various examples, the phase shift mask can be attenuated PSM or alternating PSM. The mask(s) generated by the mask fabrication 634 is used in a variety of processes. For example, such a mask(s) is used in an ion implantation process to form various doped regions in the semiconductor wafer, in an etching process to form various etching regions in the semiconductor wafer, and/or in other suitable processes.

The IC fab 640 is an IC fabrication entity that includes one or more manufacturing facilities for the fabrication of a variety of different IC products. In some embodiments, the IC fab 640 is a semiconductor foundry. For example, there may be a first manufacturing facility for the front-end fabrication of a plurality of IC products (e.g., the active regions 20/22, the source/drain features 24/26, the metal gate structures 30/32, the active region isolation structures 40, etc.), while a second manufacturing facility may provide the middle-end fabrication for the interconnection of the IC products (e.g., the frontside/backside source/drain contacts 70/82, the inter-device source/drain contacts 72, the frontside/backside gate contacts 74/84, etc.) and a third manufacturing facility may provide the back-end fabrication for the interconnection and packaging of the IC products (e.g., the frontside/backside via contacts 78/88A, the frontside/backside metal lines 80/90, etc.), and a fourth manufacturing facility may provide other services for the foundry entity.

The IC fab 640 uses the mask (or masks) fabricated by the mask house 630 to fabricate the IC device 660. Thus, the IC fab 640 at least indirectly uses the IC design layout 622 to fabricate the IC device 660. In some embodiments, a semiconductor wafer 642 is fabricated by the IC fab 640 using the mask (or masks) to form the IC device 660. The semiconductor wafer 642 includes a silicon substrate or other proper substrate having material layers formed thereon. Semiconductor wafer further includes one or more of various doped regions, dielectric features, multilevel interconnects, and the like (formed at subsequent manufacturing steps).

The IC manufacturing system 600 is shown as having the design house 620, mask house 630, and IC fab 640 as separate components or entities. However, it should be understood that one or more of the design house 620, mask house 630, and IC fab 640 are part of the same component or entity.

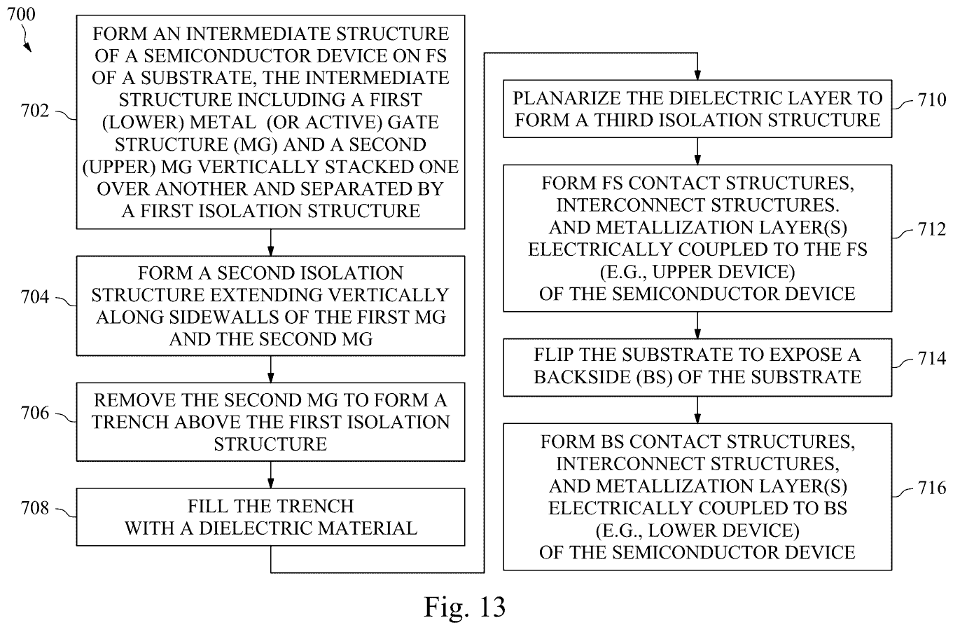

FIG. 13 illustrates a flowchart of a method 700 for forming a semiconductor device (hereafter referred to as device for simplicity), in portion or in entirety, according to one or more embodiments of the present disclosure. In some embodiments, the method 700 may be implemented to manufacture the device 100B and the device 200, in portion or in entirety, as described above in reference to FIGS. 4-6 and 7-9, respectively. It is noted that the method 700 is merely an example and is not intended to limit the present disclosure. Accordingly, it is understood that additional operations may be provided before, during, and after the method 700, and that some other operations may only be briefly described herein.

Referring to FIG. 13, components of an intermediate structure of the device 100B or the device 200 described above is formed on a frontside FS of a substrate at operation 702. The intermediate structure includes a lower (or first) metal gate structure (similar in structure to the lower metal gate structure 182L or any of the metal gate structures 30 described above, or lower metal gate structure 982L described below) and an upper (or second) metal gate structure (similar in structure to the upper metal gate structure 182U or any of the metal gate structures 32 described above, or upper metal gate structure 982U described below) vertically stacked over the first metal gate structure along the third direction, the metal gate structures being separated by a first isolation structure (e.g., the intermediate layer 156 described above, intermediate layer 990 described below). The first metal gate structure and the second metal gate structure engage corresponding active regions (e.g., the lower one of the fins 128, the upper one of the fins 128, the lower active regions 20, or the upper active regions 22 described above) to form a lower device (e.g., any of the lower devices 210L, 220L, 230L, 240L described above, or lower device 910L described below) and an upper device (e.g., any of the upper devices 210U, 220U, 230U described above, or upper device 910U described below), respectively.

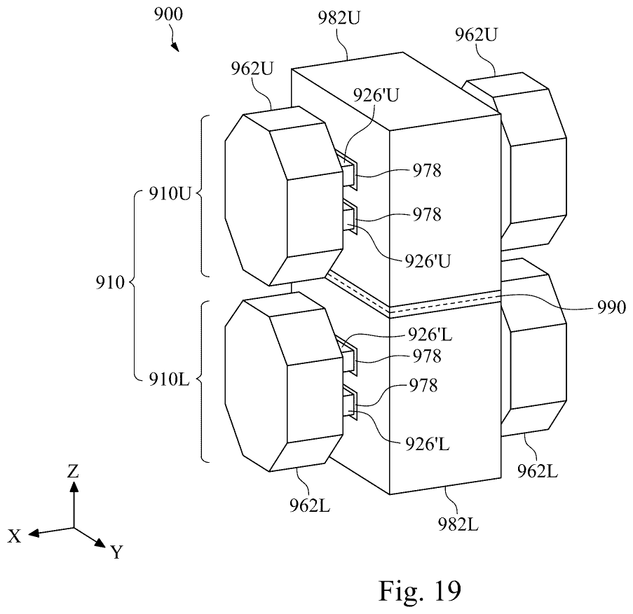

In the present embodiments, operations of the method 700 are described in reference to a semiconductor device 900 (hereafter referred to as device 900 and having an example structure as shown in FIG. 19 in a three-dimensional perspective view), according to one or more embodiments of the present disclosure. In this regard, consistent with the description regarding the devices 100A, 100B, and 200, the device 900 includes a plurality of upper devices (e.g., an upper or second device 910U) vertically stacked over a plurality of lower devices (e.g., a lower or first device 910L) along the third direction. In this regard, the lower device 910L is disposed in closer proximity to the backside BS than the upper device 910U.

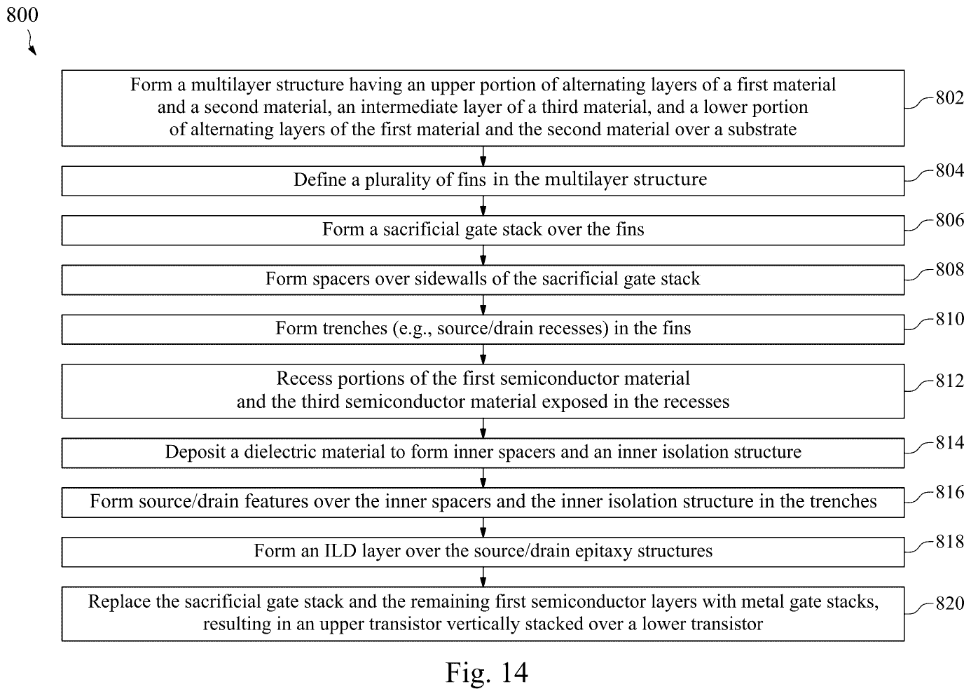

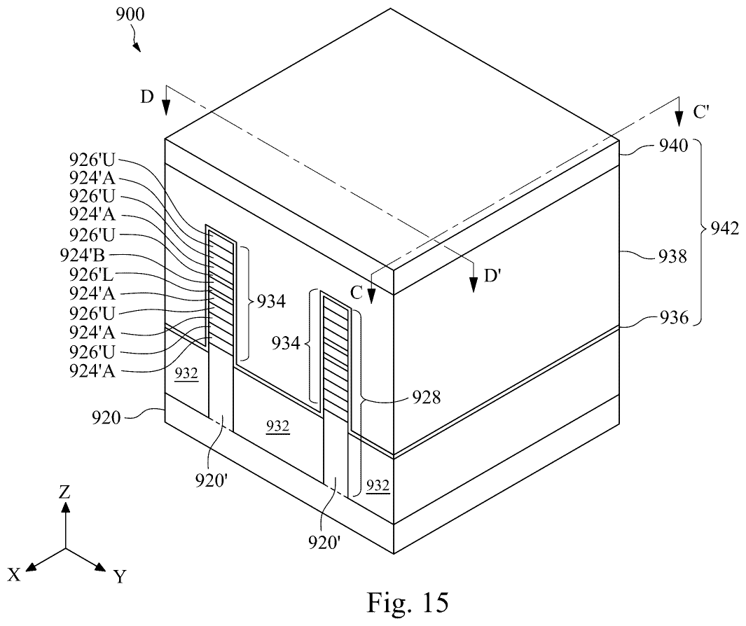

FIG. 14 illustrates a flowchart of the method 800 for forming an intermediate structure of the device 900. In some embodiments, the method 800 may be implemented at the operation 702 described above. It is noted that the method 800 is merely an example and is not intended to limit the present disclosure. Accordingly, it is understood that additional operations may be provided before, during, and after the method 800, and that some other operations may only be briefly described herein. In some embodiments, operations of the method 800 may be associated with perspective and cross-sectional views of the device 900 at various fabrication stages as shown in FIGS. 15-19, which are discussed in detail below.

Referring to FIGS. 14 and 15, a multilayer structure 922′ of alternating first semiconductor layers 924′A, 924′B (or first nanosheets) and second semiconductor layers 926′U, 926′L (or second nanosheets) is formed over the substrate 920 at operation 802.

In some embodiments, the substrate 920 includes an elementary semiconductor material such as Si. In some embodiments, the substrate 920 includes a semiconductor-on-insulator (SOI) structure. For example, the substrate 920 may include a buried oxide (BOX) layer formed by a process such as separation by implanted oxygen (SIMOX) or other suitable technique, such as wafer bonding and grinding. The substrate 920 may include other suitable semiconductor materials.

In some embodiments, the multilayer structure 922′ includes an upper portion having alternating first semiconductor material (e.g., the first semiconductor layers 924′A) and second semiconductor material (e.g., the second semiconductor layers 926′U); a lower portion having alternating first semiconductor material and second semiconductor material (e.g., the second semiconductor layers 926′L); and an intermediate layer of a third semiconductor material (e.g., a middle first semiconductor layer 924′B) different from the first semiconductor material and the second semiconductor material in composition. The intermediate layer of the third semiconductor material is interleaved between two layers (e.g., middle second semiconductor layers 926′M) of the second semiconductor material that are configured as dummy layers.

In FIG. 15, the multilayer structure 922′ is illustrated in a state after formation of fins, as described herein. The multilayer structure 922′ includes alternatingly arranged first semiconductor layers 924′A, 924′B and second semiconductor layers 926′U (i.e., the nanosheets 926U′), 926′L (i.e., the nanosheets 926L′). The first semiconductor layers 924′A, 924′B and the second semiconductor layers 926′U, 926′L include semiconductor materials having different etch selectivity and/or oxidation rates. For example, in some embodiments the first semiconductor layers 924′A, 924′B include SiGe, and the second semiconductor layers 926′U, 926′L include Si. In some embodiments, the first semiconductor layers 924′A, 924′B have different concentrations of Ge, resulting in different etch selectivity and/or oxidation rates therebetween. In some embodiments, the first and second semiconductor layers 924′A, 924′B, 926′U, 926′L are formed by a deposition process, such as epitaxy. For example, epitaxial growth of the layers of the multilayer structure 922′ is performed by a molecular beam epitaxy (MBE) process, a metalorganic chemical vapor deposition (MOCVD) process, and/or other suitable epitaxial growth processes.

A plurality of fins 928 (alternatively referred to as active regions 928) are defined in the multilayer structure at operation 804 by one or more etching processes. Isolation structures 932 may be formed over the substrate and between the fins. Each fin 928 includes a substrate portion 920′ of the substrate 920, and a portion 934 of the multilayer structure 922′. The portion 934 of the multilayer structure 922′ is sometimes referred to as a stack of semiconductor layers 934. In some embodiments, the fins 928 are fabricated using suitable processes, such as double-patterning or multi-patterning processes. For example, in one or more embodiments, a sacrificial layer is formed over a substrate and patterned using a photolithography process. Spacers are formed alongside the patterned sacrificial layer using a self-aligned process. The sacrificial layer is then removed, and the remaining spacers are then used to pattern the fins 928 by etching the multilayer structure 922′ and the substrate 920. Example etch processes include, but are not limited to, dry etch, wet etch, reactive ion etch (RIE), and/or other suitable processes. In FIG. 15, two fins 928 are illustrated; however, the number of the fins is not limited to two.

In some embodiments, the isolation structures 932 including an insulating material are formed over the substrate 920 and in trenches (not depicted) between the fins 928 at the operation 804. For example, the insulating material is deposited over the substrate 920 and the fins 928. Example insulating materials of the isolation structures 932 include, but are not limited to, SiO₂, fluorine-doped silicate glass (FSG), SiN, SION, SIOCN, SiCN, a low-k dielectric material, the like, or combinations thereof. The deposition of the insulating material includes a suitable method, such as low-pressure chemical vapor deposition (LPCVD), plasma enhanced CVD (PECVD) or flowable CVD (FCVD). Then, a planarization operation, such as a CMP process and/or an etch-back process, is performed such that the tops of the fins 928 are exposed from the insulating material. A portion of the insulating material between adjacent fins 928 is removed. The remaining portion of the insulating material configures the isolation structures 932. The partial removal of the insulating material includes dry etch, wet etch, or the like.

Subsequently, still referring to FIGS. 14-16, a sacrificial gate structure 942 including a sacrificial gate dielectric layer 936, a sacrificial gate electrode layer 938, and a mask structure 940 is formed over the fins 928 at operation 806. In some embodiments, the sacrificial gate dielectric layer 936 includes one or more layers of dielectric material, such as SiO₂, SiN, a high-k dielectric material, the like, or combinations thereof. In some embodiments, the sacrificial gate dielectric layer 936 is deposited by a CVD process, a sub-atmospheric CVD (SACVD) process, a FCVD process, an atomic layer deposition (ALD) process, a physical vapor deposition (PVD) process, or other suitable process. In at least one embodiment, the sacrificial gate electrode layer 938 comprises polycrystalline silicon (polysilicon). In some embodiments, the mask structure 940 comprises a multilayer structure. In some embodiments, the sacrificial gate electrode layer 938 and the mask structure 940 are formed by one or more processes such as layer deposition, for example, CVD (including both LPCVD and PECVD), PVD, ALD, thermal oxidation, e-beam evaporation, or other suitable deposition techniques to obtain the device 900.

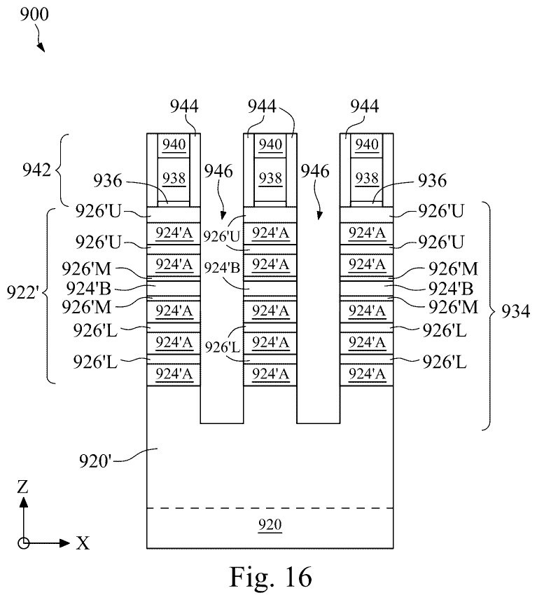

The sacrificial gate structures 942 are formed by one or more pattern and/or etch processes performed on the deposited sacrificial gate dielectric layer 936, sacrificial gate electrode layer 938, and mask structure 940. An example pattern process comprises a lithography process. An example etch process comprises dry etch (e.g., RIE), wet etch, other etch methods, and/or combinations thereof. Each sacrificial gate structure 942 comprises a portion of each of the sacrificial gate dielectric layer 936, sacrificial gate electrode layer 938, and mask structure 940. The sacrificial gate structures 942 extend, or are elongated, along the second direction. In FIG. 16, three sacrificial gate structures 942 are illustrated; however, the number of the sacrificial gate structures 942 is not limited to two.

Referring to FIGS. 14 and 16, corresponding spacers 944 are then formed over sidewalls of the sacrificial gate structure 942 at operation 808. The spacers 944 are formed on sidewalls of the sacrificial gate structures 942. For example, the spacers 944 are formed by first depositing a conformal layer that is subsequently etched back to form the spacers 944. The spacers 944 comprises a dielectric material, such as SiO₂, SiN, SiC, SiOC, SiON, SiCN, SiOCN, the like, or combinations thereof. In some embodiments, the spacers 944 comprise multiple layers of dielectric materials.

Still referring to FIGS. 14 and 16, trenches 946 (also referred to as source/drain recesses) are formed in each of the fins 928 at operation 810. Exposed portions of the stacks of semiconductor layers 934 of the fins 928 not covered by the sacrificial gate structures 942 and the spacers 944 are selectively removed, e.g., by one or more suitable etch processes, such as dry etch, wet etch, or a combination thereof, to form the trenches 946, which are alternatively referred to as source/drain recesses.

Subsequently, exposed portions of the first semiconductor material (e.g., exposed edge portions of each of the first semiconductor layers 924A′) and an entirety of the third semiconductor material (e.g., the middle first semiconductor layer 924B′) in the trenches 946 are then recessed or etched to form intermediate openings (not depicted) at operation 812. The second semiconductor material (e.g., the second semiconductor layers 926′U, 926′L) remain substantially intact during the recessing at operation 812.

Specifically, in FIG. 16, a lowermost one of the second semiconductor layers 926′U and an uppermost one of the second semiconductor layers 926′L are designated as the middle second semiconductor layers 926′M which sandwich therebetween the middle first semiconductor layer 924′B. The middle second semiconductor layers 926′M and the middle first semiconductor layer 924′B are not configured to form channel regions of the upper device 910U and lower device 910L. Edge portions of the first semiconductor layers 924′A, 924′B and second semiconductor layers 926′U, 926′L, 926′M are exposed in the trenches 946. The trenches 946 also expose portions of the substrate portion 920′, resulting in the device 900 as depicted in FIG. 16.

Subsequently, the exposed edge portions of the first semiconductor layers 924′A are replaced. In some embodiments, such replacement is implemented by a selective wet etch process. The selective wet etch process further completely (or substantially completely) removes the first semiconductor layer 924′B in the middle of the stack of semiconductor layers 934. For example, in embodiments where the first semiconductor layers 924′A, 924′B include SiGe, and the second semiconductor layers 926′U, 926′L, 926′M include Si, a selective wet etch is configured to etch the first semiconductor layer 924′B at a highest etch rate, the first semiconductor layers 924′A at a second highest etch rate, and the second semiconductor layers 926′U, 926′L, 926′M at a slowest etch rate. As a result, the exposed edge portions of each of the first semiconductor layers 924′A and an entirety (or substantially an entirety) of each of the first semiconductor layer 924′B are removed, whereas the second semiconductor layers 926′U, 926′L, 926′M are substantially unchanged.

Subsequently, a dielectric material is deposited in the intermediate openings to form inner spacers 954 and an inner isolation structure 956 at operation 814. Examples of the dielectric material forming the inner spacers 954 and inner isolation structure 956 include SiO₂, SiN, SiCN, SiOC, SiOCN, the like; a high-k dielectric material, such as HfO₂, ZrOx, ZrAlOx, HfAlOx, HfSiOx, AlOx, the like; other suitable dielectric materials; or combinations thereof. In some embodiments, the inner spacers 954 and inner isolation structure 956 comprise different dielectric materials. In some embodiments, a composition of the inner isolation structure 956 is selected to exhibit etching selectively with respect to the neighboring components, such as the middle second semiconductor layers 926′M. In an example process, the inner spacers 954 and inner isolation structure 956 are formed by depositing a conformal layer of the dielectric material, using a conformal deposition process, such as ALD, followed by an anisotropic etching to remove portions of the conformal layer other than the inner spacers 954 and inner isolation structure 956.

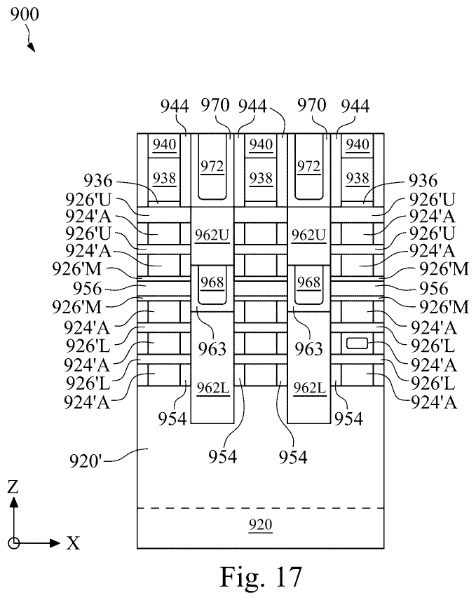

Referring to FIGS. 14 and 17, lower source/drain features 962L and upper source/drain features 962U are formed over the inner spacers 954 and the inner isolation structures 956 in the trenches 946 at operation 816. In some embodiments, a liner 963 and a dielectric layer 968 are formed over upper surfaces of the lower source/drain features 962L before forming the upper source/drain features 962U. In the example configuration in FIG. 17, the lower/upper source/drain features 962L, 962U include epitaxy structures and are sometimes referred to as lower/upper source/drain features 962L, 962U. In some embodiments, the lower source/drain features 962L and the upper source/drain features 962U are configured to have different conductivity types analogous to the source/drain features 162L and 162U or the source/drain features 24 and 26.

The lower source/drain features 962L are formed over, and in contact with, the exposed portions of the substrate portions 920′, and exposed edge portions of the second semiconductor layers 926′L. Example epitaxial growth processes for growing the source/drain features 962L, 962U include CVD, ALD, MBE, or the like. In some embodiments, the lower source/drain features 962L are grown to a height above the uppermost second semiconductor layer 926′L, and then top portions of the lower source/drain features 962L are partially removed, e.g., by a dry etch or wet etch, so that upper surfaces of the remaining lower source/drain features 962L are at a level of the uppermost first semiconductor layer 924′A immediately under the lower middle second semiconductor layer 926′M, as illustrated in FIG. 17.

The liner 963 is formed at least over the upper surfaces of the lower source/drain features 962L, and exposed side faces of the middle second semiconductor layers 926′M, inner isolation structure 956. In some embodiments, the liner 963 includes SiN. In an example process, the liner 963 includes a conformal layer formed by a conformal process, such as an ALD process. The dielectric layer 968 is formed over the liner 963 and over the lower source/drain features 962L. In some embodiments, the dielectric layer 968 comprises the same material as the isolation structures 932 and/or is formed by the same method as the isolation structures 932. The liner 963 and dielectric layer 968 are removed outside the trenches 946, and partially removed inside the trenches 946, e.g., by a dry etch or wet etch. As a result, upper surfaces of the liner 963 and dielectric layer 968 are at a level of the lowermost first semiconductor layer 924′A immediately above the upper middle second semiconductor layer 926′M, as illustrated in FIG. 17. The liner 963 and dielectric layer 968 together provide an isolation structure between the lower source/drain features 962L and the upper source/drain features 962U to be subsequently formed thereover.

The upper source/drain features 962U are formed over, and in direct contact with, the upper surfaces of the liner 963 and dielectric layer 968, and exposed edge portions of the second semiconductor layers 926U. In some embodiments, the upper source/drain features 962U are grown to a height above the sacrificial gate dielectric layer 936, and then top portions of the upper source/drain features 962U are partially removed, e.g., by a dry etch or wet etch, so that upper surfaces of the remaining upper source/drain features 962U are at a level of the sacrificial gate dielectric layer 936, as illustrated in FIG. 17. This is an example, and a height of the upper source/drain features 962U is controllable depending on specific applications and/or processes of fabrication for the device 900.

Still referring to FIGS. 14 and 17, an ILD layer 972 is then formed over the upper source/drain features 962U at operation 818. In some embodiments, a CESL 970 is formed over the upper source/drain features 962U before forming the ILD layer 972. A chemical mechanical polishing (CMP) process is subsequently performed to planarize the CESL 970 and/or the ILD layer 972. The planarization process also removes portions of the ILD layer 972 and the CESL 970. The exposed sacrificial gate electrode layer 938 and the sacrificial gate dielectric layer 936 are removed, e.g., by one or more suitable processes, such as dry etch, wet etch, or a combination thereof.

The CESL 970 is formed over the upper source/drain features 962U before forming the ILD layer 972. Example materials of the CESL 970 include SiN, SiCN, SION, SiO₂, SiOC, SiOCN, the like, or combinations thereof. The CESL 970 may be formed by CVD, PECVD, ALD, or any suitable deposition technique. Example materials of the ILD layer 972 include SiO₂, a low-k dielectric material described above, the like, or combinations thereof. The ILD layer 972 may be deposited by a PECVD process or other suitable deposition technique to obtain the device 900 as depicted in FIG. 17.

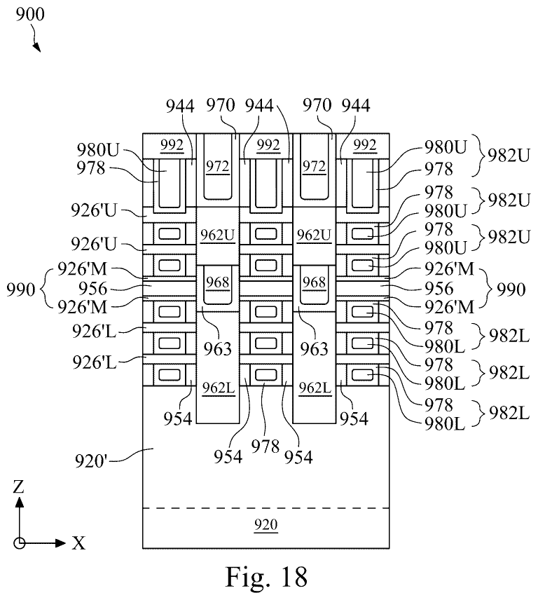

Subsequently, referring to FIGS. 14 and 18, the sacrificial gate structure 942 and the remaining portions of the first semiconductor layers 924A′ are replaced with upper metal gate structures 982U and lower metal gate structures 982L that include a gate dielectric layer 978 and a corresponding gate electrode at operation 820. The first semiconductor layers 924′A may be removed by any suitable processes, such as dry etch, wet etch, or a combination thereof. The removal of the first semiconductor layers 924′A exposes the inner spacers 954 and the second semiconductor layers 926′U, 926′L, and creates spaces between and around exposed portions of the second semiconductor layers 926′U, 926′L not covered by the inner spacers 954. The exposed portions of the second semiconductor layers 926′U, 926′L provide the nanosheets 926′U, 926′L described with respect to FIG. 19. The middle second semiconductor layers 926′M and inner isolation structure 956 are covered by the liner 963 and dielectric layer 968 and are substantially unaffected by the removal of the first semiconductor layers 924′A.

The upper metal gate structures 982U and the lower metal gate structures 982L are subsequently formed. In the depicted embodiment, the upper metal gate structures 982U formed in the upper portion of the device 900, i.e., above the inner isolation structure 956, each include the gate electrode 980U, and the lower metal gate structures 982L formed in the lower portion of the device 900, i.e., below the inner isolation structure 956, each include the gate electrode 980L. In some embodiments, the inner isolation structure 956 and the two middle second semiconductor layers 926′M are collectively referred to as an intermediate layer 990 and configured to at least partially isolate the upper metal gate structure 982U from its corresponding lower metal gate structure 982L along the third direction. In this regard, the intermediate layer 990 is alternatively referred to as the (first) isolation structure 990.

The gate dielectric layer 978 is formed over and around each of the nanosheets 926′U, 926′L. In some embodiments, the gate dielectric layer 978 includes the same material as the sacrificial gate dielectric layer 936. In some embodiments, the gate dielectric layer 978 includes a dielectric material described above in reference to the gate dielectric layer 178, such as a high-k dielectric material. In some embodiments, the gate dielectric layer 978 is formed by a conformal deposition process, such as an ALD process.

The gate electrode 980U is formed over and around the gate dielectric layers 978, and the nanosheets 926′U, 926′L. The gate electrode 980U surrounds each of the nanosheets 926′U, i.e., is disposed above the inner isolation structure 956, and is configured to form each upper metal gate structure 982U. The gate electrode 980L surrounds each of the nanosheets 926′L, i.e., is disposed below the inner isolation structure 956, is configured to form each lower metal gate structure 982L. In some embodiments, the gate electrodes 980U and 980L each include a material described above in reference to the gate electrode 180U. In some embodiments, the gate electrode material includes one or more work function metals. Example processes for depositing the gate electrode material include, but are not limited to, PVD, CVD, ALD, electro-plating, or other suitable methods.

FIG. 19 illustrates a schematic perspective view of an embodiment of the device 900, in portion or in entirety, according to some embodiments of the present disclosure The device 900 may be fabricated using the method 800 described with reference to FIG. 14. The device 900 may correspond to a portion of the device 900 after implementing the operation 820 as depicted in FIG. 18, for example. In the depicted embodiment, the lower metal gate structure 982L is disposed in closer proximity to the substrate 920 (e.g., the backside BS) than the upper metal gate structure 982U. In some embodiments, the metal gate structures 982L, 982U are separated by the first isolation structure 990, which is also referred to as the intermediate layer 990. In some embodiments, as described in reference to the devices 100A, 100B, and 200, the upper device 910U and the lower device 910L are configured to have different conductivity types, where the lower device 910L is disposed in closer proximity to the backside BS than the upper device 910U. For example, the upper device 910U may be configured as a NMOS device and the lower device 910L may be configured as a PMOS device, and vice versa. In some embodiments, the upper device 910U and the lower device 910L are configured to have the same conductivity type.

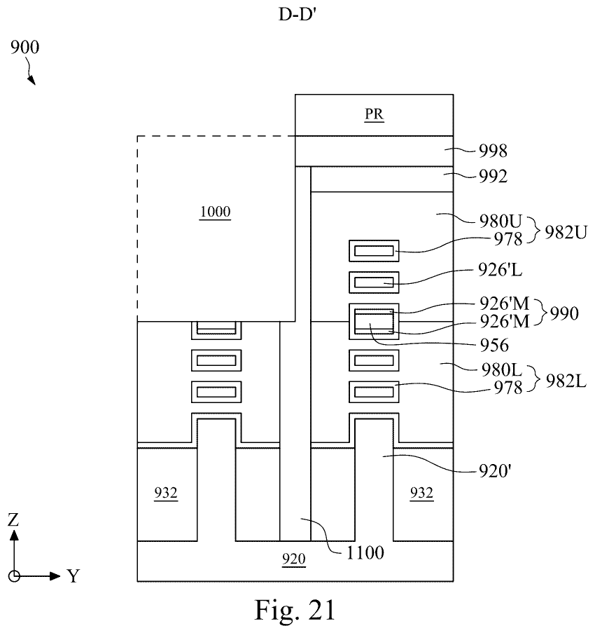

Continuing with operation 704 of the method 700, referring to FIGS. 13 and 21, a second isolation structure 1100 (e.g., the isolation structures 186 of the device 100B) is formed between two fins 928 and extending vertically along sidewalls of the lower (or first) metal gate structure 982L and the upper (or second) metal gate structure 982U formed in the device 900. In some embodiments, as depicted in FIG. 21 and further evidenced by FIGS. 1-6, the second isolation structure 1100 is configured to truncate or cut each pair of the metal gate structures 982U/L into two portions separated along the first direction. As such, similar to the description of the isolation structures 186, the second isolation structure 1100 is alternatively referred to as a gate isolation structure 1100 or a gate cut feature 1100. In some embodiments, the second isolation structure 1100 directly contacts the sidewalls of the lower metal gate structure 982L and the upper metal gate structure 982U. In some examples, the operation 704 may be omitted and the method 700 proceeds to operation 706 from the operation 702 directly. In some examples, the operation 704 may be implemented at a later stage of the method 700.

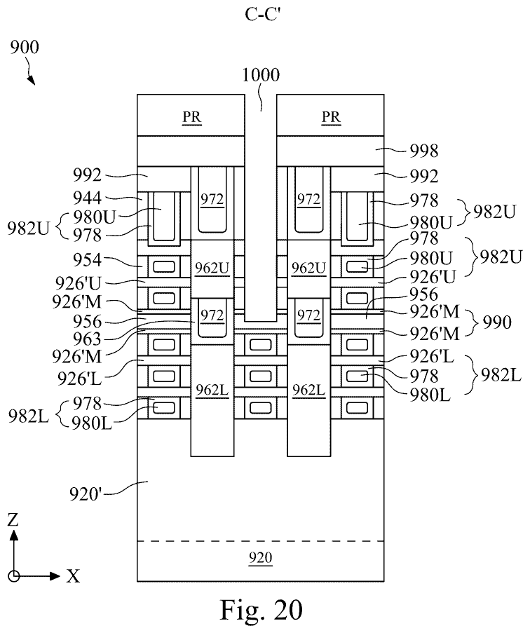

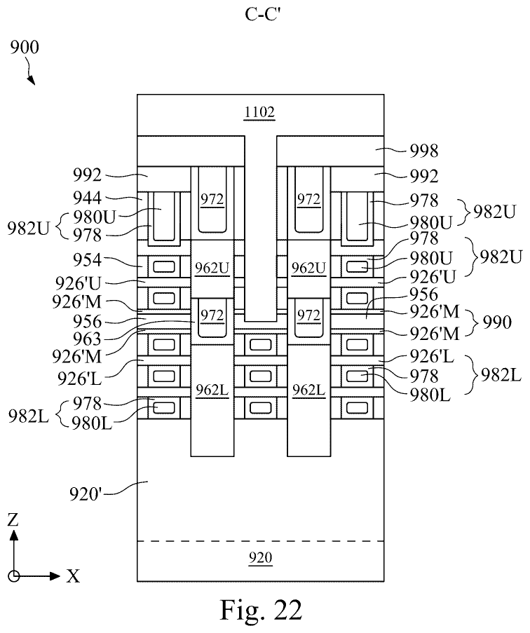

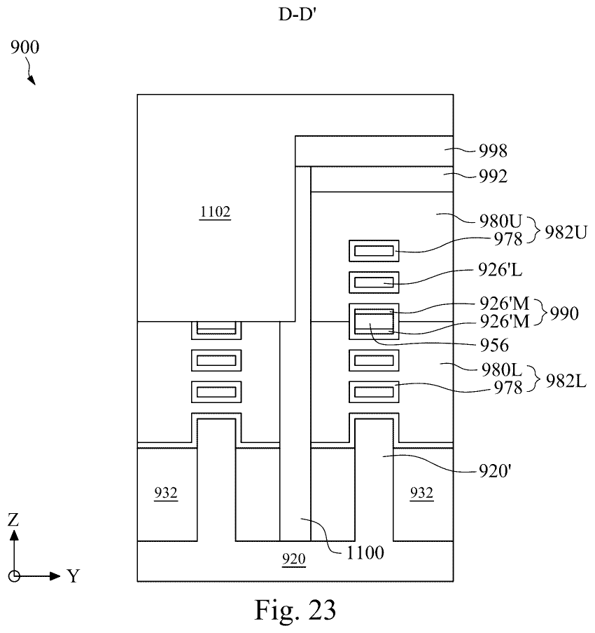

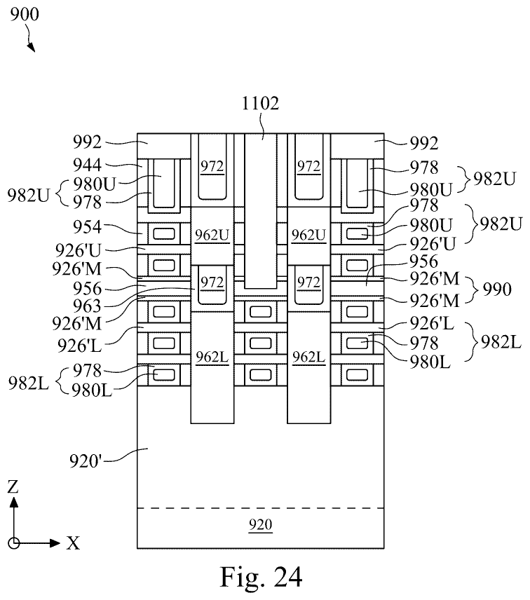

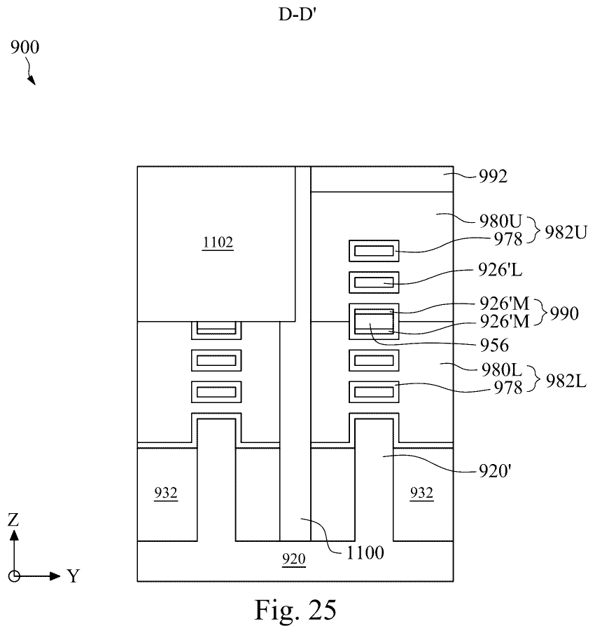

Collectively referring to FIGS. 13, 20, 21, 22, 23, 24, and 25, the upper metal gate structure 982U of the upper device 910U is removed from the device 900 and a third isolation structure 1102 (alternatively referred to as a dielectric gate structure 1102 similar to the dielectric gate structure 183U of the device 100B) is formed in its place above the first isolation structure 990 at operations 706, 708, and 710. Stated differently, the upper metal gate structure 982U is replaced with the third isolation structure 1102, which is disposed between the pair of upper source/drain features 962U along the first direction. The formation of the third isolation structure 1102 in place of the upper metal gate structure 982U renders the upper device 910U an inactive device as opposed to the active device that is the lower device 910L. In the depicted embodiment, the third isolation structure 1102 extends along the third direction to stop on an upper surface of the intermediate layer 990.

Referring to FIGS. 13, 20, and 21, the upper metal structure 982U is removed from the device 900 to form a trench 1000 at the operation 706. In some embodiments, a mask structure 998 including a dielectric material, such as SiN, is first formed over the device 900 to protect portions of the device 900 not intended to be etched. Subsequently, a patterned mask PR is formed over the device 900, where the patterned mask PR exposes a portion of the mask structure 998 over the second metal gate structure 982U to be removed. The patterned mask PR may include a photoresist material capable of being patterned using a photolithography technique. Subsequently, the mask structure 998 is patterned using the patterned mask PR as an etch mask to expose the second metal gate structure 982U, which is then removed to form the trench 1000 using a suitable etching process, such as dry etch, wet etch, RIE, or other suitable processes. The patterned mask PR may then be removed using any suitable method, such as plasma ashing or resist stripping.

In some embodiments, the trench 1000 exposes the inner isolation structure 956 by removing the upper metal gate structure 982U, the nanosheets 926′U, the upper one of the middle second semiconductor layers 926′M, and, in some instances, an upper portion of the inner isolation structure 956 to ensure complete removal of the upper metal gate structure 982U. In some embodiments, referring to FIG. 21, forming the trench 1000 also removes a portion of the second isolation structure 1100 along the third direction.

Referring to FIGS. 13, 22, and 23, a dielectric material is deposited in the trench 1000 at the operation 708. The dielectric material may include any suitable material, such as SiO₂, SiN, SION, SiOCN, SiCN, the like, or combinations thereof, as described above with respect to the dielectric gate structures 183L, 183U. The dielectric material may be deposited in the trench 1000 using any suitable deposition process, such as CVD, ALD, PVD, the like, or combinations thereof.

Referring to FIGS. 13, 24, and 25, the dielectric material is then planarized to form the third isolation structure 1102 at the operation 710. The dielectric material may be planarized using a CMP process, resulting in the third isolation structure 1102 to be substantially coplanar with the mask structure 992 disposed over the remaining upper metal gate structures 982U.

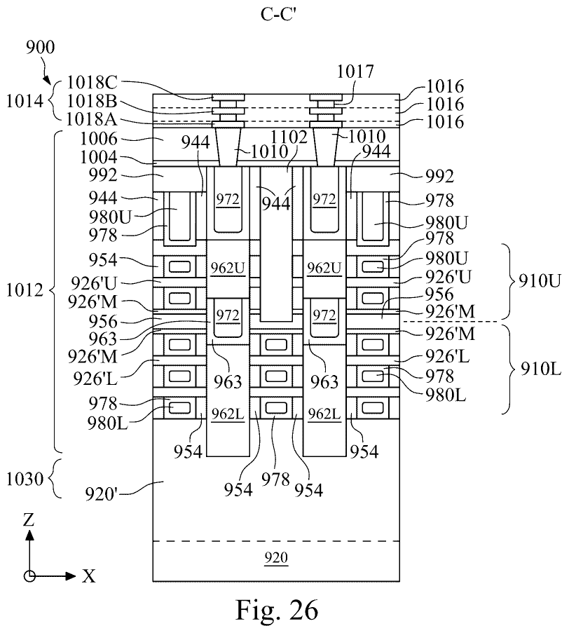

Referring to FIGS. 13 and 26, frontside contact structures are formed over and electrically coupled to the frontside of the device 900, including the upper device 910U, at operation 712. The frontside contact structures may include frontside source/drain contacts 996U (e.g., the frontside source/drain contacts 70) electrically coupled to at least some of the upper source/drain features 962U (e.g., the source/drain features 26) from the frontside FS of the substrate 920. The contact structures may further include frontside gate contacts (e.g., the frontside gate contacts 74, etc., of the device 200) electrically coupled to those upper metal gate structures 982U not depicted in FIG. 26 (e.g., the frontside metal gate structures 32) from the frontside FS of the substrate 920. In the present embodiments, because one of the upper metal gate structures 982U is replaced with the third isolation structure 1102, the device 900 does not include a frontside gate contact electrically coupled to the third isolation structure 1102, which contributes to the further reduction of capacitance in the device 900.

In some embodiments, forming the frontside source/drain contacts 996U includes patterning the ILD layer 972 to form trenches exposing the upper source/drain features 962U. A silicide layer 994 is formed over the exposed source/drain features 962U in the trench, and then the frontside source/drain contacts 996U are form in each trench and over the silicide layer 994. Example conductive materials of the frontside source/drain contacts 996U include Cu, Co, Ru, Al, Ti, Ta, TiN, TaN, Pt, the like, or combinations (or alloys) thereof. The conductive material of the frontside source/drain contacts 996U may be deposited by any suitable process, such as PVD, ECP, or CVD, and planarized by a CMP process, for example.

Still referring to FIGS. 13 and 26, frontside interconnect structures (e.g., frontside via contacts 1010) and metallization layers are subsequently formed over and electrically coupled to the frontside contact structures of the device 900 at the operation 712. In some examples, forming the frontside via contacts 1010 (e.g., the frontside via contacts 78) may include patterning the stack of the mask structure 992, the ILD layer 1006, and the CESL 1004 to form via openings, and then filling the via openings with a conductive material described above with respects to the various conductive features of the device 200. The conductive material may subsequently be planarized using a CMP process, resulting in the frontside via contacts 1010.

Thereafter, a multilayer interconnect (MLI) structure 1014 over and electrically coupled to the frontside source/drain contacts 996U and any frontside gate contacts, for example. The MLI structure 1014 includes a plurality of frontside metal lines 1018A (e.g., the frontside metal lines 80 in the frontside metallization layer M0), 1018B (e.g., the frontside metal lines 92 in the frontside metallization layer M1), and 1018C, and frontside via contacts 1017 formed over the frontside via contacts 1010. In some embodiments, the metal lines 1018A are formed in metallization layer M0, the metal lines 1018B immediately over the metal lines 1018A are formed in metallization layer M1, and so on. The MLI structure 1014 further includes various ILD layers 1016 in which the metal lines and the via contacts are embedded. Although not depicted herein, additional dielectric layers, frontside via contacts, and frontside metal lines may be formed over the frontside metal lines 1018C as a part of the MLI 1014.

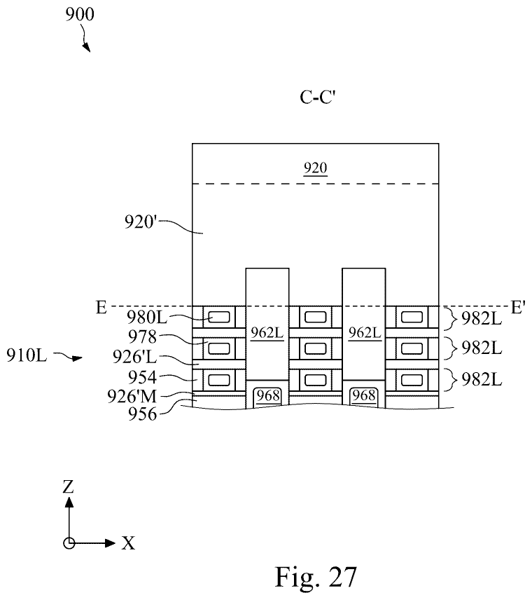

Referring to FIGS. 13 and 27, the substrate 920 is flipped to expose the backside BS of the substrate 920 in preparation for fabricating the backside components of the device 900 at operation 714. Subsequently, the flipped substrate 920 is polished along line EE′ using a CMP process, for example, to remove excess portions of the substrate 920 and expose a backside of the lower devices 910L, including a backside of the lower metal gate structures 982L and the lower source/drain features 962L.

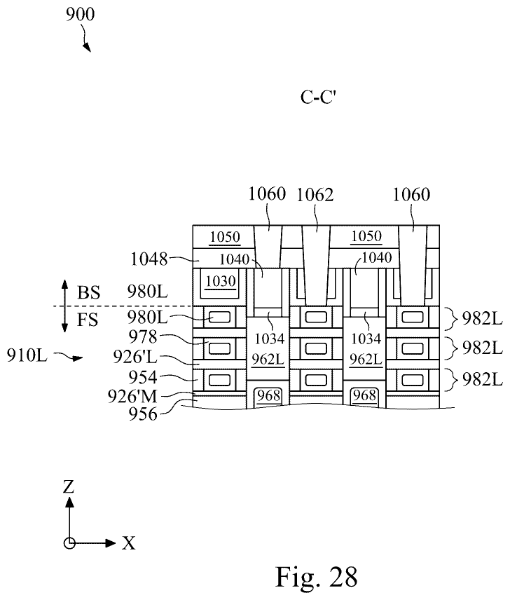

Referring to FIGS. 13 and 28, backside contact structures, interconnect structures, and metallization layers structurally analogous to those on the frontside FS of the device 900 are formed over and electrically coupled to the backside BS of the lower device 910L at operation 716. The backside contact structures, interconnect structures, and metallization layers may be formed in processes similar to those of the corresponding frontside features and are thus only briefly described below.

In some embodiments, dielectric layers 1028 and 1030 are formed on the backside of the lower device 910L. The dielectric layers 1028 and 1030 are patterned to form trenches in which a silicide layer 1034 and backside source/drain contacts 1040 (e.g., the backside source/drain contacts 82) over the silicide layer 1034 are formed. In this regard, the backside source/drain contacts 1040 are electrically coupled to the backside of the lower source/drain features 962L (e.g., the source/drain features 24). Subsequently, dielectric layers 1048 and 1050, analogous to the dielectric layers 1028 and 1030, respectively, are formed over the backside source/drain contacts 1040. The dielectric layers 1048 and 1050 are patterned to form trenches in which backside via contacts 1060 (e.g., the backside via contact 88A) and backside gate contact 1062 (e.g., the backside gate contacts 84 of the device 200) are formed and electrically coupled to their respective backside source/drain contacts 1040 and lower metal gate structures 982L, respectively. Although not depicted herein, at least one backside metal line (e.g., the backside metal lines 90) may be formed as portions of a backside metallization layer BMO electrically coupled to at least the backside gate contact 1062 to facilitate transmission of signals (e.g., the output signal ZN depicted in FIGS. 7 and 9) from the backside BS to the frontside FS as described in detail above with respect to the device 200. Furthermore, additional dielectric layers, backside via contacts, and backside metal lines may be formed over the backside metal lines.

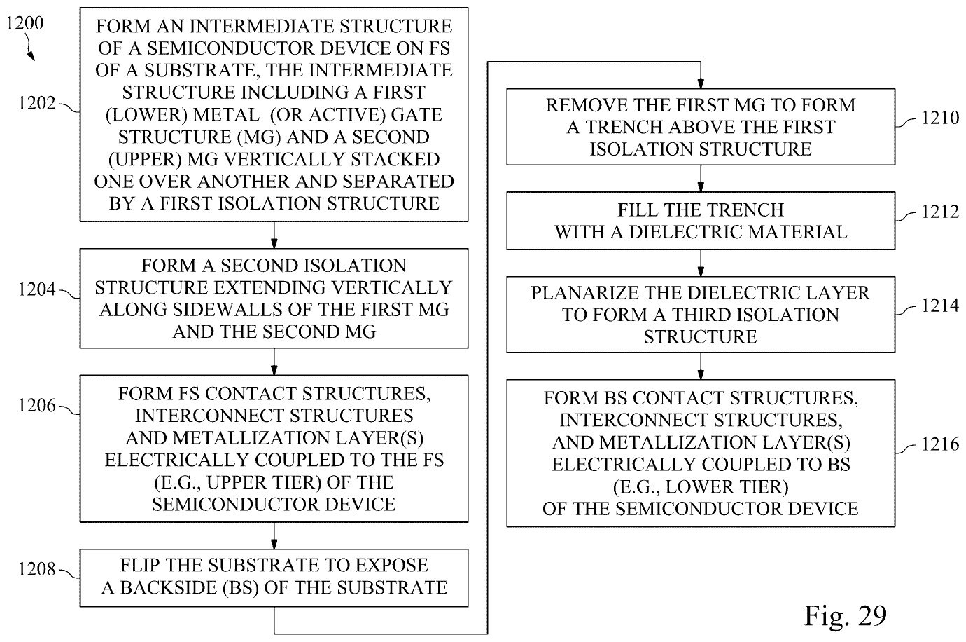

FIG. 29 illustrates a flowchart of a method 1200 for forming a device, in portion or in entirety, according to one or more embodiments of the present disclosure. In some embodiments, the method 1200 may be implemented to manufacture the device 100A described above in reference to FIGS. 1-3. It is noted that the method 1200 is merely an example and is not intended to limit the present disclosure. Accordingly, it is understood that additional operations may be provided before, during, and after the method 1200, and that some other operations may only be briefly described herein. Furthermore, operations of the method 1200 may be similar to those of the method 700 described above and are therefore only briefly described below for purposes of brevity.

For purposes of simplicity, the method 1200 is described below in reference to the device 900 as depicted in FIGS. 18 and 19. For example, analogous to the operation 702, the components of the intermediate structure of the device 900 are formed on the frontside FS of the substrate at operation 1202. The intermediate structure includes the lower (or first) metal gate structure 982L and the upper (or second) metal gate structure 982U vertically stacked over the lower metal gate structure 982L along the third direction, the metal gate structures 982L, 982U being separated by the first isolation structure 990.

Subsequently, analogous to the operation 704, the second isolation structure 1100 is formed adjacent to one of the fins 928 and extending vertically along sidewalls of the metal gate structures 982L, 982U formed in the device 900 at operation 1204.

Analogous to the operation 712, the frontside contact structures, the frontside interconnect structures, and the metallization layers electrically are formed over and electrically coupled to the frontside of the device 900, including the upper device 910U at operation 1206. Thereafter, analogous to the operation 714, the substrate 920 is flipped to expose the backside BS of the substrate 920 in preparation for fabricating the backside components of the device 900 at operation 1208.

At operation 1210, the lower metal structure 982L is then removed from the backside BS of the device 900 to form a trench through a series of photolithography and etching processes similar to those described above in reference to the operation 706, with the exception that the processes of the operation 1210 are implemented from the backside BS of the substrate 920. Analogous to the operations 708 and 710, the dielectric material is deposited to fill the trench and subsequently planarized to form the third isolation structure (alternatively referred to as a dielectric gate structure similar to the dielectric gate structure 183U of the device 100B) in place of the lower metal gate structure 982U at operations 1212 and 1214, respectively. Accordingly, the formation of the third isolation structure in place of the lower metal gate structure 982L renders the lower device 910L an inactive device as opposed to the active device that is the upper device 910U.

Subsequently, analogous to the operation 716, the backside contact structures, the interconnect structures, and the metallization layers analogous to those on the frontside FS of the device 900 are formed over and electrically coupled to the backside BS of the lower device 910L.

Although the structures and methods will be discussed in terms of CFET structures devices, one of ordinary skill in the art would understand that the structures and methods are not so limited and certain aspects of the embodiments discussed are suitable for inclusion in manufacturing processes for other classes and configurations of IC devices. The structures and methods disclosed herein are equally applicable to various manufacturing processes used in achieving the vertical stack structures including both monolithic CFET manufacturing processes and sequential CFET manufacturing processes.

It will be understood that not all advantages have been necessarily discussed herein, no particular advantage is required for all embodiments or examples, and other embodiments or examples may offer different advantages.

In some aspects, the present disclosure provides a semiconductor device, including: an active gate structure disposed over a substrate; first source/drain features disposed at two opposite sides of the active gate structure; a dielectric gate structure disposed over the substrate, the dielectric gate structure and the active gate structure stacked one over another along a vertical direction perpendicular to the substrate; and second source/drain features disposed at two opposite sides of the dielectric gate structure, where the first source/drain features and the second source/drain features are of different conductivity types.

In some aspects, the present disclosure provides a semiconductor device, including: an active device disposed over a frontside of a substrate and including: a gate structure extending along a first lateral direction, and first source/drain features separated by the gate structure along a second lateral direction perpendicular to the first lateral direction; and an inactive device disposed over the frontside of the substrate, the inactive device and the active device stacked one over another along a vertical direction perpendicular to the first lateral direction, the inactive device including: an isolation structure extending along the first lateral direction; and second source/drain features separated by the isolation structure along the second lateral direction, where the first source/drain features and the second source/drain features are of different conductivity types.

In some aspects, the present disclosure provides a method, including: forming a semiconductor device on a frontside of a substrate, the semiconductor device including a first active gate and a second active gate structure stacked one over another and separated by a first isolation structure; removing one of the first active gate structure or the second active gate structure to form a trench; and forming a second isolation structure in the trench such that the first active gate structure.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device, comprising:
an active gate structure disposed over a substrate;
first source/drain features disposed at two opposite sides of the active gate structure;
a dielectric gate structure disposed over the substrate, the dielectric gate structure and the active gate structure stacked one over another along a first direction; and
second source/drain features disposed at two opposite sides of the dielectric gate structure, wherein the first source/drain features and the second source/drain features are of different conductivity types.

2. The semiconductor device of claim 1, wherein the first source/drain features are of n-type conductivity and the second source/drain features are of p-type conductivity.

3. The semiconductor device of claim 1, wherein the first source/drain features are of p-type conductivity and the second source/drain features are of n-type conductivity.

4. The semiconductor device of claim 1, further comprising a semiconductor layer extending between the first source/drain features or between the second source/drain features along a second direction perpendicular to the first direction, wherein the semiconductor layer is wrapped around by the active gate structure.

5. The semiconductor device of claim 4, further comprising an isolation structure disposed between the active gate structure and the dielectric gate structure.

6. The semiconductor device of claim 5, wherein the isolation structure includes a dielectric layer interposed between at least two semiconductor layers.

7. The semiconductor device of claim 1, further comprising an inner spacer embedded in the dielectric gate structure.

8. A semiconductor device, comprising:
an active device disposed over a frontside of a substrate and comprising:
a metal gate structure extending along a first direction, and
first source/drain features separated by the metal gate structure along a second direction perpendicular to the first direction; and
an inactive device disposed over the frontside of the substrate, the inactive device and the active device stacked one over another along a third direction perpendicular to the first direction and the second direction, the inactive device including:
an isolation structure extending along the first direction; and
second source/drain features separated by the isolation structure along the second direction, wherein the first source/drain features and the second source/drain features are of different conductivity types.

9. The semiconductor device of claim 8, wherein:
the isolation structure is a first isolation structure, and
the semiconductor device further comprises a second isolation structure disposed between one of the first source/drain features and one of the second source/drain features.

10. The semiconductor device of claim 8, further comprising a gate isolation structure extending along the second direction, wherein a sidewall of the gate isolation structure extends along a sidewall of the metal gate structure and a sidewall of the isolation structure in the third direction.

11. The semiconductor device of claim 10, wherein the sidewall of the gate isolation structure directly contacts the sidewall of the metal gate structure and the sidewall of the isolation structure.

12. The semiconductor device of claim 10, wherein:
the isolation structure is a first isolation structure, and
the semiconductor device further comprises a second isolation structure disposed between one of the first source/drain features and one of the second source/drain features.

13. The semiconductor device of claim 8, further comprising an intermediate layer disposed between the metal gate structure and the isolation structure.

14. The semiconductor device of claim 8, further comprising:
a first inner spacer disposed between one of the first source/drain features and the metal gate structure; and
a second inner spacer disposed between one of the second source/drain features and the isolation structure, wherein the first inner spacer and the second inner spacer are aligned along the third direction.

15. The semiconductor device of claim 14, further comprising a third inner spacer disposed between one of the second source/drain features and the isolation structure, the third inner spacer disposed between the first inner spacer and the second inner spacer along the third direction.

16. The semiconductor device of claim 8, wherein:
the substrate includes a backside opposite to the frontside,
the active device is disposed in closer proximity to the backside of the substrate than the inactive device, and
the semiconductor device further comprises a metallization layer disposed on the backside of the substrate and electrically coupled to the active device.

17. A method, comprising:
forming a semiconductor device on a frontside of a substrate, the semiconductor device including a first active gate structure and a second active gate structure stacked one over another and separated by a first isolation structure;
removing one of the first active gate structure or the second active gate structure to form a trench; and
forming a second isolation structure in the trench.

18. The method of claim 17, further comprising forming a third isolation structure extending along sidewalls of the first active gate structure and the second active gate structure before removing one of the first active gate structure or the second active gate structure.

19. The method of claim 17, wherein forming the second isolation structure includes depositing a dielectric layer in the trench and planarizing the dielectric layer.

20. The method of claim 17, wherein:
the substrate includes a backside opposite to the frontside,
the first active gate structure is disposed in closer proximity to the backside of the substrate than the second active gate structure, and
the method further comprises forming a metallization layer over the backside of the substrate, the metallization layer electrically coupled to the first active gate structure.
